(19) United States
(12) Patent Application Publication
(10) Pub. No.: US 2026/0266884 A1
(43) Pub. Date: Sep. 10, 2026

(54) ENHANCED REAL-TIME ELECTROMAGNETIC FIELD DETECTION AND ANALYSIS SYSTEM

(71) Applicant: TechHold LLC, Minneapolis, MN (US)

(72) Inventors: Greg Fuchs, River Falls, WI (US); Terrence R. Noe, Sebastopol, CA (US); David Anderson, Excelsior, MN (US)

(21) Appl. No.: 19/558,076

(22) Filed: Mar. 5, 2026

Related U.S. Application Data
(60) Provisional application No. 63/767,481, filed on Mar. 5, 2025.

(51) Int. Cl. G01R 29/08; G01R 33/02

(52) U.S. Cl. CPC G01R 29/0878; G01R 29/0892; G01R 33/0206

(57) ABSTRACT

An enhanced electromagnetic field detection and analysis system employs three orthogonal magnetic field sensors within a Faraday cage construction to detect and analyze electromagnetic field events. The system features high-speed data acquisition operating at 8 billion samples per second coupled with a circular buffer memory system storing 16,000 sample points, enabling detection of field strengths from 100 V/m to 100,000 V/m and frequencies between 10 MHz and 10 GHz. The system performs real-time Fast Fourier Transform analysis up to 7 GHz while maintaining detection capabilities at distances up to 100 meters. Housed in an anodized aluminum exterior with compartmentalized interior spaces, the system provides continuous monitoring, sophisticated frequency analysis, and threat assessment through building perimeter software, operating without sacrificial elements and maintaining performance in various environmental conditions. The system enables identification of specific electromagnetic signatures through advanced signal processing and maintains historical data for forensic analysis.

### CROSS-REFERENCE TO RELATED APPLICATIONS

The present application claims priority from U.S. Provisional Patent Application No. 63/767,481, filed on Mar. 5, 2025, the disclosure of which is hereby incorporated by reference in its entirety.

### BACKGROUND

The detection and analysis of electromagnetic field events has become increasingly critical in both civilian and defense applications. Electromagnetic pulses (EMPs) and other electromagnetic disturbances can pose significant threats to electronic systems, infrastructure, sensitive equipment and even an individual's health. The ability to detect, characterize, and analyze these electromagnetic events in real-time is essential for implementing effective protective measures and response strategies.

Existing electromagnetic field detection systems typically employ either electric field sensors or basic magnetic field detection methods. These conventional systems often suffer from significant limitations, including narrow detection ranges, vulnerability to damage from high-strength fields, and inability to perform sophisticated frequency analysis in real-time. Electric field measurement systems frequently require sacrificial elements that must be replaced after exposure to strong electromagnetic events, leading to system downtime and increased maintenance costs.

Current solutions also struggle with environmental factors, often failing to maintain consistent detection capabilities in various weather conditions or outdoor settings. Many existing systems are limited by their inability to capture and analyze rapid electromagnetic events, particularly those with extremely short duration or high repetition rates. Furthermore, traditional detection systems typically lack the capability to perform comprehensive frequency analysis, which is crucial for identifying specific types of electromagnetic events and their sources.

Previous advances in this field, as described in U.S. Pat. No. 8,773,107, introduced fundamental improvements in electromagnetic field detection. However, these systems still face limitations in terms of their ability to perform continuous high-speed data buffering, real-time frequency analysis, and multiple sequential event detection. Additionally, existing solutions often lack the capability to operate independently and maintain consistent performance across varying environmental conditions while providing detailed frequency characterization of detected events.

Furthermore, existing electromagnetic detection systems generally lack the sophisticated signal processing capabilities necessary for identifying specific electromagnetic signatures associated with particular devices or weapons. The inability to perform real-time frequency analysis up to the gigahertz range, combined with limited sampling rates and buffer capacities, creates significant gaps in detection and characterization capabilities.

### SUMMARY

The present disclosure describes various embodiments of an enhanced electromagnetic field detection and analysis system capable of detecting, measuring, and characterizing electromagnetic field events across an expanded range of field strengths and frequencies. The system provides significant improvements over existing solutions through its sophisticated frequency analysis capabilities, continuous high-speed data buffering, and robust environmental resistance.

In one aspect, the present disclosure provides systems and methods for detecting and analyzing electromagnetic disturbances. In certain embodiments, an electromagnetic detection system includes a detector housing configured as a Faraday cage. The detector housing includes circuitry that is connected to multiple magnetic field sensors arranged to detect electromagnetic fields from multiple spatial directions. The sensors may include orthogonally oriented magnetic antennas configured to detect electromagnetic fields across a wide range of field strengths and frequencies. The detected signals may be captured using a high-speed data acquisition system included in the circuitry, and stored within a memory architecture that preserves signal information surrounding detected events.

In some embodiments, the data acquisition system may sample electromagnetic signals at extremely high sampling rates, such as several billion samples per second, enabling capture of short-duration electromagnetic events. The system may store sampled data within a circular buffer memory that continuously records signal data and preserves samples occurring before and after a trigger event. Captured signals may then be analyzed using signal processing techniques including frequency-domain analysis to determine characteristics of detected electromagnetic disturbances.

In certain implementations, the system may perform frequency analysis using techniques such as Fast Fourier Transform processing to identify frequency components of detected signals. The resulting signal characteristics may be used to classify electromagnetic signatures or identify potential sources of electromagnetic disturbances. In some embodiments, the detection system may further include filtering components, EMP protection elements, and internal shielding structures to protect internal electronics from high-energy electromagnetic events.

In another aspect, a method for detecting electromagnetic disturbances may include continuously monitoring electromagnetic fields using multiple magnetic field sensors, acquiring signal data at high sampling rates, storing sampled data in a circular buffer memory, performing frequency-domain analysis on the acquired signals, and identifying electromagnetic events based on characteristics of the analyzed signals. The method may further include generating visual indications of detected electromagnetic events through a monitoring interface.

In some embodiments, multiple detector units may be deployed across a monitored area and may communicate with a central monitoring computer. The monitoring computer may receive event data from the detectors, correlate detections across multiple devices, and display detected events through a graphical user interface. The interface may provide information regarding event timing, signal strength, waveform characteristics, and frequency content associated with detected electromagnetic disturbances.

In another aspect, certain embodiments may include signal processing architectures that estimate signal frequency using multiple parallel signal paths having different frequency responses. For example, an input signal may be divided into multiple paths including high-pass and low-pass filter paths. Detection circuitry may measure signal amplitudes associated with the respective filter paths, and a processor may estimate the signal frequency based on relative amplitudes measured across the paths. Such architectures may enable estimation of signal frequency characteristics without requiring full high-speed waveform reconstruction.

These and other aspects of the disclosed systems and methods enable detection, characterization, and monitoring of electromagnetic disturbances using high-speed sampling architectures, frequency analysis techniques, and distributed detector networks.

### BRIEF DESCRIPTION OF THE DRAWINGS

FIG. 1 is an example block schematic diagram of an electromagnetic detector system deployed at a facility.

FIG. 2 is an example system for detecting electromagnetic signals, according to a possible embodiment of the present disclosure.

FIG. 3A is an example antenna useable to detect high field pulses, according to a possible embodiment of the present disclosure.

FIG. 3B is an example antenna useable to detect high field pulses, according to a second possible embodiment of the present disclosure.

FIG. 4 is an example schematic block diagram of a circuit useable to detect high or low electromagnetic fields, according to a possible embodiment of the present disclosure;

FIG. 5 is an example schematic block diagram of a circuit useable to detect high field electromagnetic fields, according to a further possible embodiment of the present disclosure.

FIG. 6 is a schematic block diagram of a high field electromagnetic pulse detection system including a high field detector apparatus, according to a possible embodiment of the present disclosure.

FIG. 7 is a schematic block diagram of a high field electromagnetic pulse detection system incorporated into a shielded enclosure, according to a possible embodiment;

FIG. 8 is an example schematic depiction of an antenna structure useable in connection with the high field circuits discussed herein, according to a first possible embodiment.

FIG. 9 is an example schematic depiction of an antenna structure useable in connection with the high field circuits discussed herein, according to a second possible embodiment.

FIG. 10 is an example schematic depiction of an antenna structure mounted to an electromagnetically-shielded enclosure, according to a possible embodiment of the present disclosure.

FIG. 11 is a schematic block diagram of a low field electromagnetic pulse detection system, according to a first possible embodiment of the present disclosure.

FIG. 12 is a schematic block diagram of a low field electromagnetic pulse detection system, according to a second possible embodiment of the present disclosure.

FIG. 13 is a schematic block diagram of a low field electromagnetic pulse detection system, according to a third possible embodiment of the present disclosure.

FIG. 14 is a schematic block diagram of a low field electromagnetic pulse detection system, according to a fourth possible embodiment of the present disclosure.

FIG. 15 is a schematic block diagram of an electronic computing device capable of forming aspects of the present disclosure.

FIG. 16 is a flowchart of methods and systems for detecting an electromagnetic pulse event, according to a possible embodiment of the present disclosure.

FIG. 17 illustrates an example high-speed signal acquisition and digital down-conversion architecture in which an input signal is split into phase-shifted signal paths and sampled by high-speed analog-to-digital converters.

FIG. 18 illustrates an example envelope-following detector architecture for one sensing channel.

FIG. 19 illustrates an example multi-path signal processing architecture for estimating signal frequency using parallel signal paths having different frequency responses.

FIG. 20 illustrates an example frequency response comparison for parallel high-pass and low-pass filter paths used for frequency discrimination.

FIG. 21 illustrates an example graphical user interface for monitoring electromagnetic detection events. The interface displays a geographic map showing detector locations and detected electromagnetic events, along with panels presenting event details, waveform information, frequency spectrum data, and system alarm status information.

### DETAILED DESCRIPTION

The present disclosure describes systems and methods for detecting, measuring, and analyzing electromagnetic field events. The disclosed systems provide improved detection capability across a wide range of field strengths and frequencies while enabling detailed characterization of electromagnetic events through high-speed sampling and frequency analysis.

In some embodiments, the system detects electromagnetic disturbances such as electromagnetic pulses (EMP), intentional electromagnetic interference (IEMI), and other transient electromagnetic events. The system may be configured to operate in civilian, industrial, infrastructure protection, or defense environments.

In various embodiments, the system includes one or more electromagnetic detectors having associated circuitry positioned within a protective housing. Each detector may include magnetic field sensors, signal conditioning circuitry, high-speed data acquisition components, memory buffers, and processing circuitry configured to characterize electromagnetic events. The system may further include communication interfaces that allow detectors to transmit event information to a central monitoring computer.

The system may be capable of detecting electromagnetic fields having strengths ranging from approximately 100 volts per meter to 100,000 volts per meter and frequencies ranging from approximately 10 MHz to 10 GHz. In other embodiments, different field strength ranges and frequency ranges may be supported depending on detector configuration.

The disclosed system may perform real-time or near real-time frequency characterization of detected events and may store waveform and event information for later analysis.

The logical operations of certain aspects of the disclosure described herein are implemented as: (1) a sequence of computer implemented steps, operations, or procedures running on a programmable circuit within a computer, and/or (2) a sequence of computer implemented steps, operations, or procedures running on a programmable circuit within a directory system, database, or compiler.

### System Diagrams

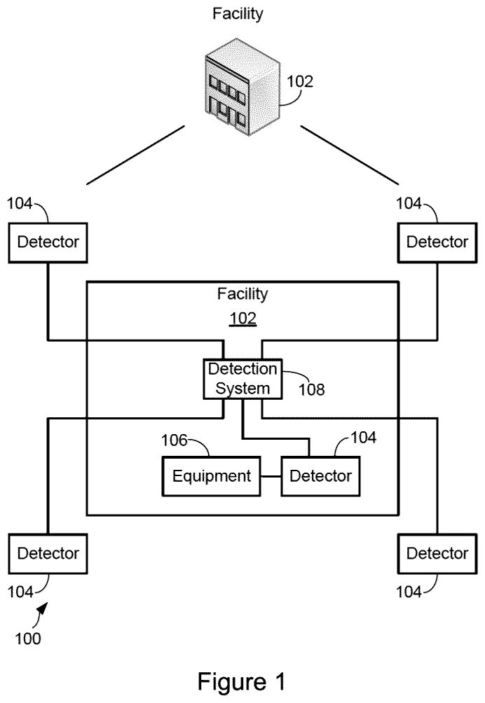

Referring now to FIG. 1, an example block schematic diagram of an electromagnetic event detector system 100 deployed at a facility 102 is shown. The electromagnetic event detector system 100 includes a plurality of detectors 104 deployed throughout the facility 102. In the embodiment shown, the detectors 104 are deployed along a perimeter of the facility 102, as well as in association with electronic equipment 106 within the facility. As such, the detectors 104 are configured to operate across a variety of temperature ranges and in a variety of weather conditions.

The detectors 104 can take any of a number of forms. In some embodiments, the detectors 104 can be a stand alone high field or low field electromagnetic event detector, as described herein. In such embodiments, the detectors 104 can optionally also include other sensors, such as temperature, carbon monoxide, carbon dioxide, smoke, fire, radiation, or chemical sensors as well. Additionally, one or more different types of detectors can be used at a single facility 102.

In the embodiment shown, each of the detectors 104 is communicatively connected to a detection system 108, which in various embodiments can be a centrally-located, shielded computing system configured to receive signals from the detectors 104. The detection system 108 can analyze the signals received from the detectors and, based on one or more different types of calculations (as described below), can detect the presence of a high field or low field electromagnetic event, such as an EMP/IEMI event. The detection system 108 can also communicate status information regarding electromagnetic events, or observed electrical field readings, to a remote system (not shown) such as a data archival system or for purposes of alarming to a remote monitoring system, or for forensic information.

Optionally, the detection system 108 also periodically determines the state of various computing or electronic systems at the facility 102, such that, upon occurrence of an electromagnetic event, the last-known good status of that electrical or electronic equipment can be determined and restored in case damage has occurred.

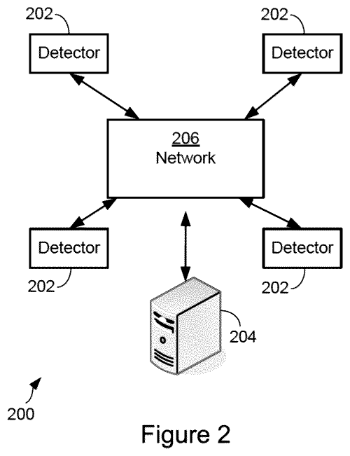

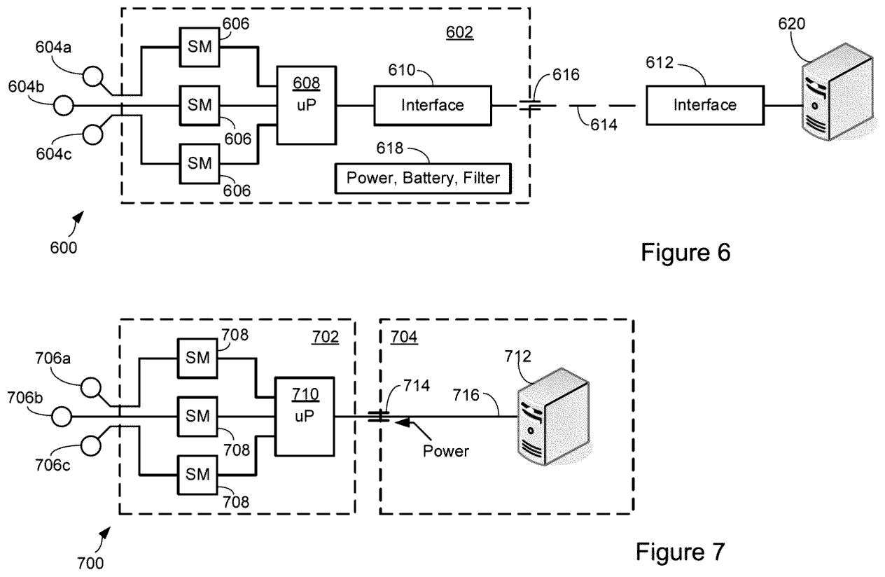

FIG. 2 provides additional details regarding an example system 200 for detecting electromagnetic signals, according to a possible embodiment of the present disclosure. In the embodiment shown, the system 200 includes a number of detectors 202 interconnected with a central detector system 204 by a network 206. In the embodiment shown, a number of detectors 202 are associated with a single central detector system 204, which is generally a computing system configured to receive signals from the detectors relating to peak values of electrical or magnetic signals received at those detectors, and determine whether such values correspond to an electromagnetic event, such as an EMP/IEMI event. In alternative embodiments, each detector 202 can have a dedicated microprocessor or computing system associated with it to detect or determine the existence of an electromagnetic event. Example arrangements of detectors using such an arrangement are illustrated in FIGS. 6-7 and 13-14, described below. In such embodiments, those separate microprocessors or computing systems can also communicate to an external system for example if centralized electromagnetic event logging or management of detectors is desired.

The network 206 can take any of a number of forms. In some embodiments, the network 206 represents a secured communications network or point-to-point network using one or more electrical or fiber optic conduits between the detectors 202 and central detector system 204, using any of a number of standard communications protocols. In certain examples, as described below, connection between a detector 202 and central detector system 204 can be accomplished using an RS-232 electrical connection, or through use of fiber optic cabling (and any of a variety of connectors and protocols). In still other embodiments, the detectors 202 and central detector system 204 can communicate using any of an umber of open networks and standards, such as the Internet. Other embodiments are possible as well.

Using the system 200 to coordinate use of detectors 202 and a central detector system 204, it is possible to determine the direction from which an electromagnetic event is detected, as well as the approximate distance to that electromagnetic event. For example, a central detector system 204 can compute an approximate location of the electromagnetic event based on the differing magnitudes and times at which electrical fields are observed at detectors spaced across a distance, if the locations of those detectors are known, and normal attenuation of the electrical field over free space is assumed.

### Time Synchronization

Referring to FIGS. 1-2, to enable accurate correlation of events across detectors 104, 202 the systems described therein may implement time synchronization mechanisms. Each detector may include an internal clock system that maintains timing information during operation.

In some embodiments a master timing source may be used to synchronize multiple detectors. Synchronization may occur through network communication or external timing sources such as GPS clocks. A master detector configuration with integrated timing or separate device may be employed. While GPS clock integration is possible with an onboard backup, GPS antennas typically require satellite visibility or repeaters and lack EMP resistance. The system employs a CMOS clock with approximately 10-year battery life. Detectors may also maintain internal battery-powered clocks to preserve timing information during power interruptions.

The system implements independent clock operation with automatic resynchronization when connected to the main computer, ensuring timing accuracy across multiple units. This capability maintains operation during power fluctuations or loss of connected systems while enabling precise coordination between multiple deployed units. If timing is sufficiently precise, data records can be compared between detectors to determine relative phase, which can be used to compute source location when precise detector locations are stored.

### Power and Battery Backup

In some embodiments detectors 104, 202 may include battery systems that maintain operation during temporary power interruptions. The existing battery is for the CMOS clock inside the detector with approximately 10 year lifetime. A larger rechargeable battery may be incorporated, continuously kept ready until power is lost, able to run the detector for a period of time if power is interrupted. Additional rechargeable batteries may allow the detector to continue operating for limited time if external power is lost. In some embodiments detectors may generate hardware trigger outputs for activating external systems such as alarms, cameras, or protective power systems.

### Communication and Security Features

Detectors 104, 202 may communicate with central systems (e.g., central computing system 204), through wired or wireless network connections. In some embodiments communication may occur through Ethernet connections, fiber optic links, and/or wireless networking systems. In example embodiments, communication traffic between detectors and monitoring systems may be encrypted to prevent data spoofing. Some embodiments may include diagnostic communication signals designed to detect unauthorized interference or attempts to disrupt detector operation. In some embodiments diagnostic or verification communications may be used to detect attempts to interfere with detector operation.

### Networked Detector Systems

In some embodiments, multiple detectors may be deployed within a facility or across multiple locations. Each detector may operate independently while communicating with a central monitoring computer through a network connection. As shown in FIG. 2, a central computer may collect event data from multiple detectors and maintain a centralized event database. By comparing detection times across multiple detectors, the system may estimate the direction or location of electromagnetic sources. The system enables multi-site correlation by comparing frequency signatures across different detection sites. Matching frequency profiles across locations can identify same-actor usage across multiple attack points, facilitating tracking of coordinated electromagnetic attacks through signature matching.

### Electromagnetic Event Detector Devices

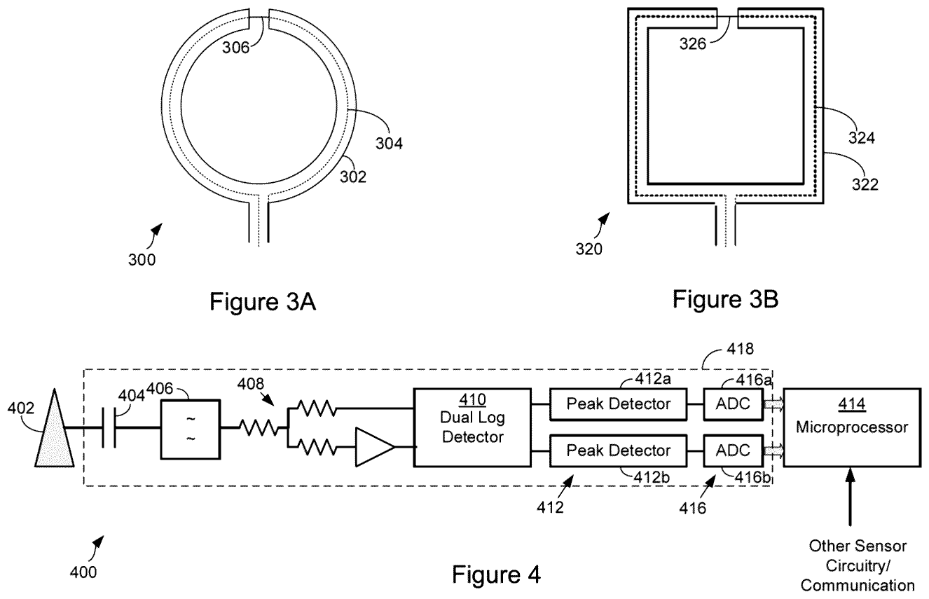

Referring now to FIGS. 3A-14, additional details regarding specific electromagnetic event detectors are described. The various example detectors and detector components are generally categorized into two types, representing high field detectors and low field detectors. Although it is recognized that one of these types of detectors is particularly designed to sense and detect certain types of electromagnetic events, that detector may also be suitable to detect other events as well. For example, a high field detector may be useable to detect low field events as well, or vice versa.

Referring now to FIGS. 3A-10, various example circuits and components of field detectors are illustrated, as well as example implementations using such a detector. FIGS. 3A and 3B illustrates antennas 300, 320 respectively, useable to detect high field pulses, according to a possible embodiment of the present disclosure. The antennas 300, 320 are, in the embodiments shown, a shielded loop magnetic antenna. For example, in FIG. 3A, the antenna 300 is a generally circular loop antenna having a loop of approximately ¼ inch or less in diameter, and including shielding (e.g., a metal sheath); in FIG. 3B, the antenna 320 is a generally rectangular loop antenna having size of approximately ¼ inch in length. Each antenna includes shielding 302, 322 (represented by solid lines) which extends around each loop 304, 324 (illustrated using dotted lines), and effectively limits induction of an electrical field on the antenna, while making the loops 304, 324 susceptible to magnetic fields. Each antenna also includes an exposed gap portion 306, 326, respectively, at which the magnetic field is induced. In particular embodiments, the antennas 300, 320 can be high field self integrating B dot antennas. Other embodiments are possible as well.

In the embodiments shown, the antennas 300, 320 are configured to output voltages that are directly proportional to the electrical field amplitude that corresponds to the component of the observed magnetic field at a given frequency at the antenna. In certain embodiments, the antennas 300, 320 are configured to output voltages of zero to five volts, depending upon the field strength of the electrical field observed (as inferred from the observed magnetic field strength). Preferably, the antennas 300, 320 have tailored inductance and resistance values to result in output of such voltages and has a sufficiently fast (nanosecond range) response times to detect EMP/IEMI pulse events.

In certain embodiments, the antennas 300, 320 have output amplitudes that in combination with an equalizer are independent of frequency, at least over a predetermined frequency range. In certain embodiments, that frequency range can include about 200 MHz to about 10 GHz; in other embodiments, the frequency range can extend from about 10 MHz to about 10 GHz.

Additionally, although the antennas 300, 320 are described as being approximately ¼ inch in diameter, other sizes or dimensions of antennas are possible as well. By changing the size of the antennas 300, 320, different ranges of frequencies can be detected. The ¼ inch or less antennas described herein are intended to be responsive across the range of frequencies in which EMP/IEMI events occur, as described in the preceding paragraph.

The system utilizes shielded loop magnetic antennas to detect magnetic fields and infer electric field strength. This approach provides significant advantages over systems that measure electric fields directly, as it eliminates the need for sacrificial elements and allows for more robust detection. The system is capable of detecting fields with strengths ranging from 100 V/m to 100,000 V/m without requiring additional attenuation. This broad detection range enables identification of both high and low-intensity electromagnetic events. The current embodiment employs three orthogonally oriented antennas capable of measuring fields from any direction across a frequency range of 100 Hz to 18+ GHz.

In use, the antennas 300, 320 can each be used to obtain measurements of far field magnetic field measurements to infer electric field intensity, and therefore to detect electromagnetic pulses or other electromagnetic events, as previously described. When placed in a far field from the electromagnetic radiation source (e.g., spaced such that a radiation source is more than several wavelengths away from the antenna), the magnetic field strength detected by the antenna, H, is directly correlated to the electric field strength component E by the impedance of free space, approximately 377Ω. This relationship can be represented by the following equation:

$$\text{?} = \overline{E} / 377 Ω$$

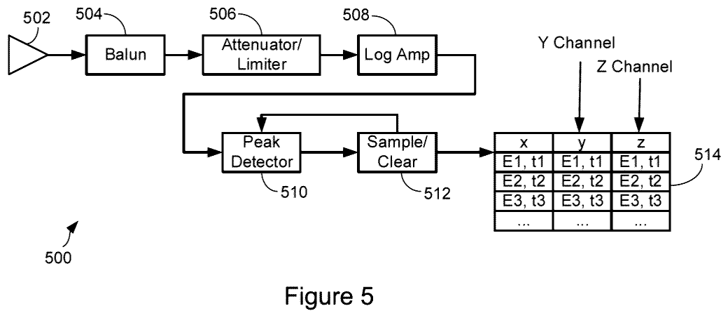

Using this relationship, a component of the electric field strength can be inferred by measuring a directional magnetic field strength. By vectorially adding such field strengths across all possible directions (e.g., using three antennas positioned normal to each other, as described in FIGS. 5-10, below), an overall electrical field strength can be inferred.

Through use of the antennas 300, 320, electrical field strengths can be inferred for fields of very high intensity, including fields in the range of 100 volts per meter to 100,000 volts per meter without additional attenuation of the inbound signal.

Referring now to FIG. 4, an example schematic block diagram of a circuit 400 is shown that is useable to inferentially detect electromagnetic fields, according to a possible embodiment of the present disclosure. The circuit 400, in the embodiment shown, is configured to be useable in either high field detectors or low field detectors, such that use with either a shielded loop magnetic antenna such as those shown in FIGS. 3A-3B can detect high field electromagnetic events, or use with a standard electrical field sensing monopole or dipole antennas can detect low field electromagnetic events. The circuit 400, in the embodiment shown, can therefore be used in a number of implementations of electromagnetic event detectors.

In the embodiment shown, the circuit 400 includes an antenna 402, which can, in various embodiments, represent a shielded loop magnetic antenna or other type of antenna, depending upon the particular intended implementation for the circuit 400. Leading from the antenna 402, a direct current circuit block 404 conditions the direct current portion of the signal received at the antenna, such that the detected portion of the received signal only represents the alternating current portion of the signal as induced by a field at the antenna (e.g., a magnetic field at a magnetic loop antenna in the case of high field event detection, or an electrical field at an electrical antenna in the case of low field event detection).

An equalizer 406 connects to the direct current circuit block 404, and compensates for the differentiating characteristics of the signal received at the antenna 402. A resistive attenuator circuit 408 scales the maximum expected antenna output threat voltage to a maximum allowable RF circuitry input voltage at a logarithmic detector 410, thereby preventing overload of the RF circuitry based on input signals received by the antenna 402. For example, if the maximum allowable input voltage for the RF circuitry is 5.5 volts and the maximum expected input voltage is higher, the resistive attenuator circuit 408 is configured to divide down the voltage in linear proportion to ensure that the RF processing circuitry is not damaged by signals received at the antenna.

In the embodiment shown, the resistive attenuator circuit 408 splits the incoming signal into two paths, for lower level signals and higher level signals. The lower level signals are amplified when passed to the logarithmic detector, to ensure that the signals received at the logarithmic detector 410 are in a range where its response is most linear. In certain embodiments, to achieve a dynamic range of over about 60 dB, separated, scaled signals are used that are in the approximately 30-40 dB range.

The logarithmic detector 410 receives signals from the resistive attenuator circuit 408, and provides a dynamic range of values to a peak detector 412. Specifically, the logarithmic detector 410 demodulates an RF input signal and outputs a baseband voltage proportional to the log of the input power. In certain embodiments, the logarithmic detector can be an ADL 5519 dual logarithmic detector, from Analog Devices, Inc. of Norwood, Massachusetts. Other logarithmic amplifies can include, for example, an AD8319 logarithmic amplified from Analog Devices, or a LT 5334 from Linear Technologies of Milpitas, California. Other logarithmic amplifiers could be used as well, depending upon the particular timing and expected signals received by the detector at the antenna 402.

The multi-stage peak detector 412 captures peak values of signals output from the logarithmic detector 410. Preferably, the peak detector has a fast rise time (e.g., less than about 3 ns) sufficient to capture narrow pulse EMP/IEMI events, and a sufficiently long hold time to allow a slower periodic sampling of that peak value. In certain embodiments, the rise time of the peak detector can detect signals as quickly as approximately 3 nanoseconds, and can hold that signal value for approximately 60 microseconds or longer (allowing kilohertz-level sampling frequencies of the peak detector, despite the narrow nature of EMP/IEMI events). Comb filtering or other techniques may be used to determine an appropriate sampling frequency.

In the embodiment shown, the peak detector 412 is a two-stage peak detector; however, other designs of peak detectors are possible as well. Additionally, in the embodiment shown, two peak detectors 412a-b are used, one for the higher-level signals and one for the lower-level signals received at the logarithmic detector 410. When the values captured by the peak detector 412 are obtained (e.g., by a microprocessor, as described below), the higher of the scaled signals is selected for determining a value of the electrical field (or an inferred value of a component of the electrical field, in the case of a high field detector arrangement).

A microprocessor 414 receives captured readings from the peak detector 412 via one or more analog to digital converters 416 (illustrated as analog to digital converters 416a-b), which format the analog output of the peak detector for use by the microprocessor. Based on the observed signal value captured by the peak detector, the microprocessor can determine the existence of an electromagnetic event (e.g. an EMP/IEMI event) according to any of a number of particular algorithms. In one example, the observed signal value is compared to a predetermined value representing harmful electromagnetic

The microprocessor 414 can perform a number of additional functions, beyond determination of electromagnetic events. For example, the microprocessor can, in certain embodiments, generate alarms or other notifications based on the determination of electromagnetic events. The microprocessor can also periodically store the state of one or more other electronic systems, such that a last known good time of a particular piece of electronic equipment can be known in the event of detection of an electromagnetic event, and can be logged alongside the existence of that electromagnetic event. Additionally, other data logging and security functions can be performed, and other sensor or detector values can be captured and logged. Other sensors can include, for example, smoke or fire sensors, gas sensors, sound or light sensors, chemical sensors, or other types of sensors.

Referring to the circuit 400 overall, it is recognized the specific values used for resistors in the resistive attenuator circuit 408 can vary according to different embodiments of the present disclosure. In certain embodiments, the range of monitored field strengths can be adjusted by changing the amount of attenuation provided by the resistive attenuator circuit 408, thereby presenting a lower or higher input voltage to the logarithmic detector 410 and peak detector 412.

It is further recognized that the portion of the circuit 400 from the direct current circuit block 404 to the peak detector(s) 412 can be replicated as a standard block 418, to allow use with different antennas, while using a common microprocessor for determining the present of an electromagnetic event. Examples in which such an arrangement is used are provided in connection with the high field designs of FIGS. 6-7, described below.

FIG. 5 is an example schematic block diagram of a circuit 500 useable to detect high field electromagnetic fields, according to a further possible embodiment of the present disclosure. The circuit 500 represents a particular implementation of the circuit described above in connection with FIG. 4, particularly suited to high field event detection.

In the embodiment shown, the circuit 500 includes an antenna 502, which, according to the various embodiments described herein relating to high field detection, can be a shielded loop magnetic antenna. A balun 504 performs signal conditioning on the received magnetic signals, and passes those signals to an attenuator/limiter circuit 506. The attenuator/limiter circuit 506 generally corresponds to the resistive attenuator circuit 408 of FIG. 4, above. A logarithmic amplifier 508 and peak detector 510 are analogous to those elements 410, 412 of FIG. 4 as well.

A sample and clear circuit 512 can be included in the circuit 500 to read the signals captured by the peak detector 510. In certain embodiments, the sample and clear circuit 512 can include an analog to digital converter and programmable circuit, such as the A/D converter 416 and microprocessor 414 of FIG. 4.

As recognized by comparing the portion of the circuit 500 from the balun 504 through the sample and clear circuit 512, this generally corresponds to and would be useable interchangeably with the standard block 418 of FIG. 4. In the embodiment shown, which is particularly used in association with high field events, the samples collected at the sample and clear circuit 512 relate to inferred electrical field components from a magnetic field having a particular orientation.

To ensure that all directions are encompassed, two additional circuit sections and antennas can be used, with the antennas placed in an arrangement where each antenna is oriented normal to the orientation of the other two antennas, (e.g., forming a three-dimensional axis), in which a first antenna captures an “x” component of a magnetic field, a second antenna captures a “y” component of the magnetic field, and a third antenna captures a “z” component of the magnetic field. As illustrated, a microcontroller 514 collects sample readings from each of these circuit sections (i.e., respective sample and clear circuits 512 associated with each oriented antenna), and infers an overall electrical field strength based on the observed three components of the magnetic field. In particular, the total electrical field estimate can be represented by the square root of the sum of squares of the directional electrical field estimates, as represented by the following equation:

$${E}_{T} = \sqrt{{E}_{x}^{2} + {E}_{y}^{2} + {E}_{z}^{2}}$$

The value of E_{T} can be periodically transmitted to a remote system for further processing, or can be analyzed to determine the existence of a high field electromagnetic event (e.g., an EMP/IEMI event). In an alternative embodiment in which accurate electrical field amplitude is less critical than simply determining the existence of a pulse, simply summing the constituent directional electrical fields can be performed.

Referring now to FIGS. 6-7, schematic block diagrams of high field electromagnetic pulse detection systems are disclosed. The schematic block diagrams illustrate example arrangements in which high field electromagnetic pulse detection systems can be implemented, although others are possible as well.

FIG. 6 illustrates a high field electromagnetic pulse detection system 600 including a high field detector apparatus 602, which in the embodiment shown represents a stand-alone component. As such, the high field detector apparatus 602 can correspond to a detector, such as those illustrated in FIGS. 1-2, above.

The high field electromagnetic pulse detection system 600 includes a plurality of shielded loop magnetic antennas. In the embodiment shown, the system 600 includes three shielded loop magnetic antenna 604a-c, each oriented to capture magnetic signals along a different axis, such that each antenna 604a-c is oriented normal to a plane formed by the other two antennas.

Signals from each of the antennas 604a-c are fed into the high field detector apparatus 602, which includes three corresponding standard circuit blocks 606. In various embodiments, the standard circuit blocks 606 can correspond to the standard block 418 of FIG. 4, or corresponding block of circuitry described in FIG. 5, above. The output of each of the standard circuit blocks 606 is fed to a microprocessor 608 within the high field detector apparatus 602, which can determine the existence of a high field event, log such events, or otherwise capture information relevant to the existence of such events (e.g., state information). The high field detector apparatus 602 includes a communication interface 610 which converts signals from the microprocessor 608 (e.g., RS-232 formatted signals, or other differential or digital signals) and converts those signals for communication external to the high field detector apparatus 602. In an example embodiment, the communication interface 610 converts the signals to fiber optic signals, and communicates with a complementary, remote communication interface 612 via a fiber connection 614. To prevent interference by the high electromagnetic event on the fiber connection 614, a waveguide beyond cutoff 616 can be included at the boundary of the housing of the high field detector apparatus 602 to ensure that internal components of that apparatus are not damaged. In such arrangements, the high field detector apparatus 602 also has an electromagnetically shielded housing (e.g., represented by the dotted line 602), preventing the high field event from damaging the apparatus 602 itself. The high field detector apparatus 602 also includes a maintenance block 618, which can provide power, backup battery, and power filtering functionality for the detector apparatus 602.

From the remote communication interface 612, captured data relating to high field events can be communicated to a computing system 620, which can log or analyze those events, combine data relating to those events with data from other types of sensing systems, communicate that data to a central detector system via an Internet connection or other networked connection, or otherwise manage the collected data.

Referring to the high field electromagnetic pulse detection system 600 overall, it is recognized that although a single high field detector apparatus 602 and computing system 620 are illustrated, arrangements of the system are possible in which multiple high field detector apparatus 602 could be associated with a single computing system, or multiple computing systems, depending upon the detection location requirements and computing resources required to monitor those detectors.

FIG. 7 illustrates a high field electromagnetic pulse detection system 700 that includes a high field detector 702 incorporated alongside a shielded enclosure 704. This arrangement may be particularly useful for detector systems used at a facility when placed in close proximity to sensitive computing systems or other electronics (e.g., the detector illustrated in FIG. 1 as associated with electronics at the facility 102). In this embodiment, a plurality of antennas 706a-c lead to standard blocks 708, which generally correspond to antennas as illustrated in FIGS. 3A-3B, and blocks as described above with respect to FIG. 6. The high field detector 702 also includes a microprocessor 710 analogous to the microprocessor 608 of FIG. 6, and a similar electromagnetically shielded enclosure (represented by dotted line 702).

In comparison to the system 600 of FIG. 6, rather than including a communication interface in this arrangement, the detector 702 is mounted directly to an enclosure 704, such that a computing system 712 can be placed within an electromagnetically shielded enclosure or rack system, and can monitor the detector 702 as previously explained. In the embodiment shown, the detector 702 can be mounted to the enclosure by using a radio frequency (RF) gasket 714 at a waveguide beyond cutoff opening in the enclosure to allow electrical communication between the microprocessor 710 of the detector 702 and the computing system 712 within the enclosure. The radio frequency gasket 714 is, in the embodiment shown, sized and positioned to prevent electromagnetic signals from penetrating the electromagnetically shielded enclosure past the waveguide beyond cutoff opening, which allows electrical communication into the enclosure 704.

In various embodiments, the electrical connection 716 between these components can be an RS-232 or RJ-45 style differential signal communicative connection. Additionally, as illustrated, power can be communicated through the RF gasket 714 and into the detector 702, such that the detector need not include a contained maintenance block, as disclosed in the system 600 of FIG. 6.

The enclosure 704 can be any of a number of styles of electromagnetically-shielding enclosures, and preferably shields from high field events, such as those detected using the high field detector 702. In various embodiments, the enclosure can be manufactured based on the techniques and systems described in U.S. Pat. No. 8,642,900, entitled “Modular Electromagnetically Shielded Enclosure”, the disclosure of which is hereby incorporated by reference in its entirety.

Although in the embodiment shown the high field detector 702 is mounted externally to the enclosure 704, in an alternative embodiment, the entire high field detector 702 and associated antennas 706a-c can be placed entirely within the enclosure 704, such that high field events would only be detected if the integrity of the enclosure itself is first breached. Other arrangements in which detectors are placed both internally and externally to the enclosure are possible as well.

As illustrated in the example detector arrangements of FIGS. 6-7, the use of a simple, inexpensive circuit allows a user to create electromagnetic event detection systems including redundant detectors for relatively low cost, and which can be used to detect electromagnetic events in various locations around a facility. Furthermore, although the antennas 604a-c and 706a-c of FIGS. 6-7 are exposed to high field events, those antennas only generate relatively low electrical responses to those fields, and can pass those low, “safe” signals to detector circuitry as described in connection with FIGS. 4-7.

### Detector Housing and Physical Construction

In some embodiments of the devices shown in FIGS. 6-7, each detector apparatus 602, 702 is contained within a housing configured to protect the detector electronics from environmental exposure and electromagnetic interference. The housing may include a conductive enclosure forming a Faraday cage that shields internal electronics from external electromagnetic disturbances. In certain embodiments the housing includes an anodized aluminum body. The body may serve multiple purposes including providing environmental protection, serving as a ground plane, and functioning as a thermal heat sink for internal electronics.

The exterior surface of the housing may be anodized or otherwise treated for corrosion resistance and environmental durability through a conductive phosphating and anodizing process. Areas that require electrical conductivity, such as grounding points or electromagnetic gasket interfaces, may be masked or otherwise protected during finishing operations to maintain conductive surfaces. The body includes a high frequency grounding point for a strap to attach to body.

The housing may include compartmentalized internal spaces that isolate sensitive detection components from computational electronics or power circuitry. This compartmentalization may reduce internally generated electromagnetic noise and improve measurement accuracy. As power draw and computing power increase for frequency analysis or other functions, segregation of computing, power, or antenna detection areas may be needed to reduce internal noise. In some embodiments additional electromagnetic shielding or absorptive materials may be positioned between sensing components and processing electronics to reduce internally generated electromagnetic noise. Internal absorbers can be added to reduce internal reflection and noise. Additionally, in some embodiments communication lines may pass through waveguide-beyond-cutoff structures to maintain electromagnetic shielding integrity.

The housing may be configured for indoor or outdoor installation. The system maintains unattenuated detection capabilities in outdoor environments through sophisticated environmental protection design. Environmental protection may include sealing against moisture, dust, and temperature variations to protect electronics, signal and power connections. A portion is EM shielded and a portion is not (contains electrical/communication connections). Fiber can be used for communication and attached through a waveguide-beyond-cutoff into the protected portion. Power to detector is filtered before entering the shielded portion.

Thermal management may be provided through passive heat dissipation using the housing body. The body is designed to radiate heat effectively and act as a heat sink, with anodizing in a light/reflective color to minimize heating in sunlight. In some embodiments additional thermal management elements may be included, such as heat spreaders, cooling fins, waveguide ventilation structures to provide airflow, forced-air cooling systems (fans), and/or solid-state heat pumps or radiators attached to the body. The system architecture allows for optional active cooling elements, though this is avoided when possible to maintain reliability. The waveguide design balances thermal management requirements with environmental sealing needs. The housing may include EMP filtering elements for incoming power and communication connections to protect internal electronics from high-energy electromagnetic disturbances. The system includes an EMP-shielded and filtered AC/DC converter to power detectors. Power supply can be filtered only if located far away from detectors or in an area largely protected from radiated pulses. An enclosed UPS or battery for attached detectors can be added.

### Magnetic Field Sensors

In certain embodiments the system utilizes magnetic field sensing elements to detect electromagnetic events. The sensors may include shielded loop magnetic antennas configured to measure the magnetic component of electromagnetic fields. Magnetic field sensing may provide advantages compared to systems that directly measure electric fields. For example, magnetic sensing can enable robust detection of high-energy electromagnetic events without requiring sacrificial sensing components.

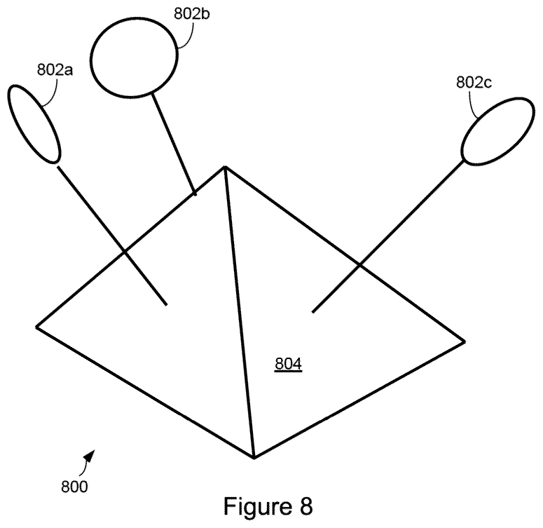

In some embodiments the detector includes three magnetic field sensors arranged orthogonally to one another, as illustrated in FIGS. 8-10. This configuration enables measurement of electromagnetic fields from substantially any direction in three-dimensional space. Each magnetic sensor may be configured to detect field strengths across a wide dynamic range. In certain implementations the sensors may detect electromagnetic fields having strengths from approximately 100 V/m to 100,000 V/m without requiring attenuation circuitry. In some embodiments the antenna and signal path may be designed to provide a substantially flat frequency response across the detector operating range.

In some embodiments, the system may infer electric field strength from measured magnetic field strength values using relationships between electric and magnetic fields in the far-field region. Examples of such magnetic field sensors are described in U.S. Pat. No. 8,773,107, entitled “Electromagnetic Field Detection Systems and Methods”, the disclosure of which is hereby incorporated by reference in its entirety.

Alternative embodiments may include different numbers of magnetic sensors or different sensor arrangements depending on the desired detection characteristics.

Referring specifically to FIGS. 8-10, various structural arrangements of antennas and mechanical layouts for high field electromagnetic detection devices are illustrated. FIG. 8 is an example schematic depiction of an antenna structure 800 useable in connection with the high field circuits discussed herein, according to a first possible embodiment. In this embodiment, three antennas 802a-c are generally mounted on and extend from a pyramidal base 804. Each antenna 802a-c is in this embodiment a shielded loop magnetic antenna, and is oriented in direction and such that the loop is oriented normal to the direction of each of the other two antennas, to ensure a three-dimensional capture of magnetic fields near the antenna structure 800. Optionally, one or more circuits, such as the standard module described in FIGS. 4-5, could be included in the base 804 of the antenna structure 800, or an electrical connection can extend from the base 804 to such circuitry.

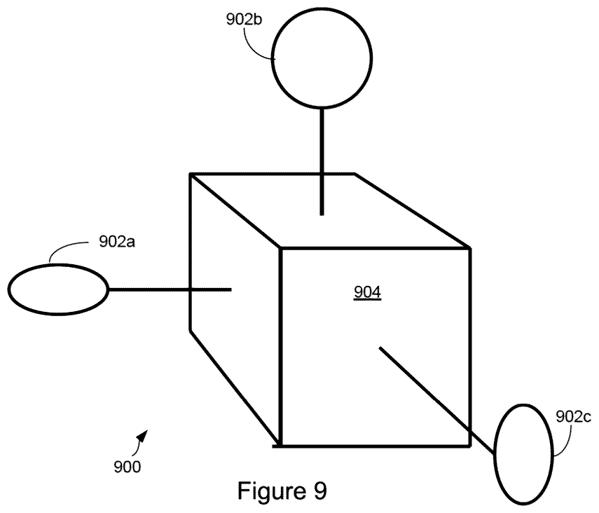

FIG. 9 illustrates a second example of an antenna structure 900 useable in connection with the high field circuits. In this embodiment, again three shielded loop magnetic antennas 902a-c are used, and each extends along an axis in a direction normal to the other two antennas, and has a loop that is oriented in a direction normal to the orientation of the other two loop antennas. The antennas 902a-c are mounted in this embodiment to a cubic or rectangular base 904, which can also house either one or more standard modules or other circuits for processing signals received at the antennas, or forwarding those signals to such circuits for processing.

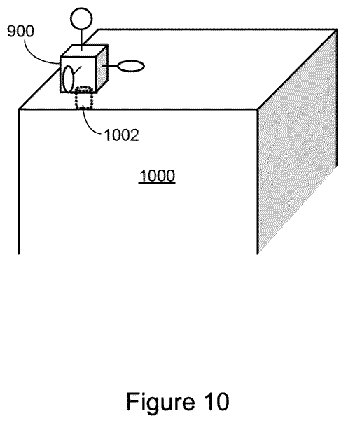

Now referring to FIG. 10, an example schematic depiction of the antenna structure 900 of FIG. 9 is illustrated as mounted to an electromagnetically-shielded enclosure 1000 is shown. In this embodiment, a gasket 1002 is located on a bottom side of the base 900 adjoining the enclosure 1000, to provide electrical communication through a waveguide-beyond-cutoff connection between circuitry in the base (e.g., the circuitry disclosed as included within the detector 702 of FIG. 7), and circuitry or computing systems within the enclosure 1000 (e.g., a computing system such as system 712 of FIG. 7).

Although the antenna structure 900 of FIG. 9 is illustrated as mounted on the enclosure 1000, it is recognized that other antenna structures, such as structure 800 of FIG. 8 could be used in connection with mounting a detector external to an enclosure. Other arrangements of antennas and antenna structures could be used as well.

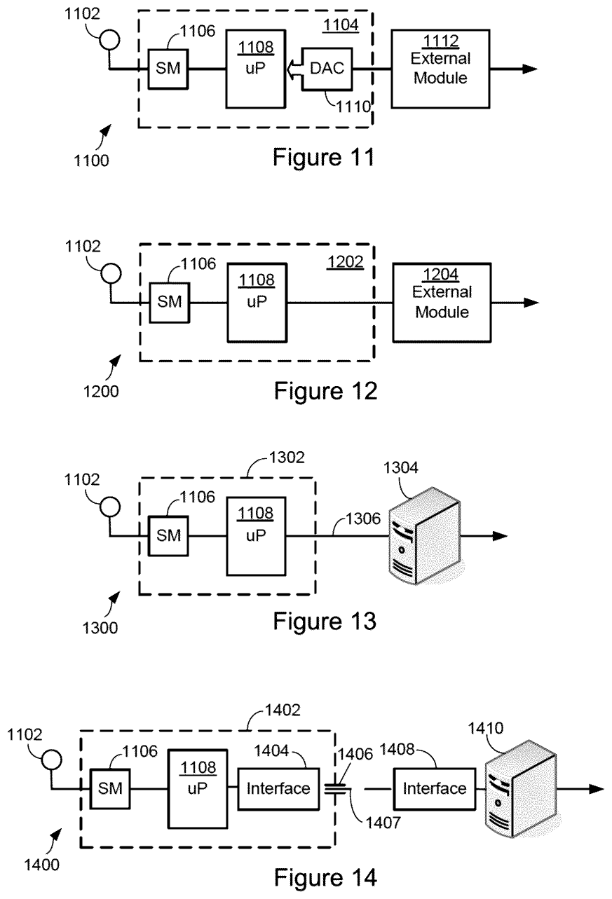

Referring now to FIGS. 11-14, arrangements of devices and systems for detecting low field events are illustrated, according to various embodiments of the present disclosure. The embodiments illustrated in FIGS. 11-14 operate according to analogous principles to those of the high field event devices, but require less concern regarding shielding of (1) output data from the detector, and (2) input signals from an antenna, at least because the expected signals to which such devices and systems are exposed are not expected to cause immediate damage to those systems.

FIGS. 11-12 refer to arrangements in which a low field electromagnetic detector can be integrated with an existing communications module used for remote sensing. FIG. 11 is a schematic block diagram of a low field electromagnetic pulse detection system 1100, according to a first possible embodiment. The system 1100 includes an antenna 1102 interconnected to a low field detector device 1104. In the embodiment shown, the antenna can be an electrical antenna, such as a short monopole antenna, or other types of similar antennas. The detector device 1104 generally includes a single standard block 1106, which can correspond to the standard blocks disclosed in the circuits of FIGS. 4-5, above.

As with the high field detector arrangements of FIGS. 4-7, the low field detector device 1104 includes a microprocessor 1108 communicatively connected to the standard block 1106, which is capable of capturing and storing peak signal values for the electromagnetic field as observed at the antenna 1102.

In the embodiment shown, the low field detector device 1104 also includes a digital to analog converter 1110, which allows the device 1104 to communicate the captured data from the microprocessor 1108 to an external module module 1112 having an analog input data connection. In certain embodiments, the external module 1112 can be configurable to communicate with remote computing systems via a network or Internet connection, or via wireless connection. For example, the external module 1112 can be, in certain embodiments, a remote sensor monitoring and aggregation system.

FIG. 12 is a schematic block diagram of a second example low field electromagnetic pulse detection system 1200. The system 1200 generally includes an antenna 1102 interconnectable to a low field detector device 1202. The low field detector device 1202 includes a standard circuit module 1106 and microprocessor 1108, as in the system 1100 of FIG. 11. However, in contrast to detector device 1104 of FIG. 11, the device 1202 is configured to directly communicate with a digital external module 1204. As such, in this embodiment no digital to analog converter is required, and the communicative connection to the digital external module 1204 is also digital, rather than analog.

In both the arrangements of FIGS. 11 and 12, the communicative connection between the remote system (e.g., remote systems 1112, 1204) can also be configured to deliver power to the detector devices 1104, 1202, respectively. However, in alternative embodiments, those devices can be configured to include separate power connections, or can include circuitry to provide battery power to the circuitry within the standard circuit module 1106 and microprocessor 1108.

Referring now to FIGS. 13-14, additional arrangements of low field detection systems are illustrated in which the detector modules are arranged as a stand-alone system configured to communicate with a remote computing system, rather than using interconnection to an external module. FIG. 13 is a schematic block diagram of a low field electromagnetic pulse detection system 1300, which generally includes an antenna 1102 communicatively connected to a low field detector device 1302. The low field detector device 1302 generally corresponds to the same device 1202 of FIG. 12 (i.e., it also includes a standard circuit module 1106 and microprocessor 1108), but communicates to a remote computing system 1304 via a standardized communication connection 1306, which, in the embodiment shown, can be an RS-232 or RJ-45 twisted pair connection. Other network connections are possible as well.

FIG. 14 is a schematic block diagram of a low field electromagnetic pulse detection system 1400, according to a further possible embodiment. The low field electromagnetic pulse detection system 1400 includes an antenna 1102 communicatively connected to a low field detector device 1402, which includes a standard circuit module 1106 and microprocessor 1108, as well as a communication interface 1404. The communication interface 1404 is configured to convert communication signals between an electrical format associated with the microprocessor 1108 (e.g., the RS-232 or RJ-45 twisted pair signaling described in connection with FIG. 13) to signals of another media type (e.g., fiber optic signals). In this embodiment, the low field detector device 1402 also includes a waveguide beyond cutoff 1406 at a boundary of the low field detector device 1402, configured to filter extraneous signals on an associated optical fiber 1407 interconnecting the communication interface 1404 and a remote communication interface 1408, which is configured to provide a complementary optical-to-electrical conversion for communication of the signals to a remote computing systems 1410.

Referring to the low field detector arrangements of FIGS. 11-14 overall, it is recognized that each of these arrangements can also be used as stand-alone detectors or as integrated with one or more shielded enclosures, as described above with respect to the high field detectors of FIGS. 6-7. Additionally, use of the low-field detectors of FIGS. 11-14 entirely within an enclosure will provide additional advantages, because detection of any low field event within an enclosure could signify that the enclosure's electromagnetic shielding has somehow been compromised, and could signal that fact prior to exposure of any of the other electrical or electronic components within that enclosure to a potentially damaging high field event. For example, low field detectors could be used to indicate that some seal has failed on an enclosure, or that a door or other aperture to the enclosure remains ajar, or other analogous event has occurred. In some arrangements, a low field detector could be placed entirely within a shielded enclosure, and a complementary low level electromagnetic emitter could be placed outside of the enclosure. Upon breach of the shielded enclosure, the detector would determine the existence of the breach, due to the persistent electromagnetic fields present external to the enclosure due to the emitter.

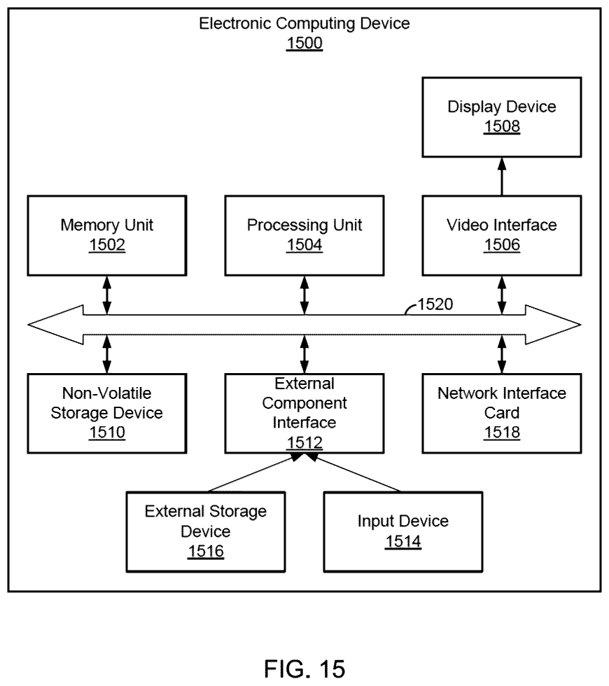

FIG. 15 is a block diagram illustrating example physical components of an electronic computing device 1500, which can be used to execute the various operations described above, and provides an illustration of further details regarding any of the computing systems described above. A computing device, such as electronic computing device 1500, typically includes at least some form of computer-readable media. Computer readable media can be any available media that can be accessed by the electronic computing device 1500. By way of example, and not limitation, computer-readable media might comprise computer storage media and communication media.

As illustrated in the example of FIG. 15, electronic computing device 1500 comprises a memory unit 1502. Memory unit 1502 is a computer-readable data storage medium capable of storing data and/or instructions. Memory unit 1502 may be a variety of different types of computer-readable storage media including, but not limited to, dynamic random access memory (DRAM), double data rate synchronous dynamic random access memory (DDR SDRAM), reduced latency DRAM, DDR2 SDRAM, DDR3 SDRAM, Rambus RAM, or other types of computer-readable storage media.

In addition, electronic computing device 1500 comprises a processing unit 1504. As mentioned above, a processing unit is a set of one or more physical electronic integrated circuits that are capable of executing instructions. In a first example, processing unit 1504 may execute software instructions that cause electronic computing device 1500 to provide specific functionality. In this first example, processing unit 1504 may be implemented as one or more processing cores and/or as one or more separate microprocessors. For instance, in this first example, processing unit 1504 may be implemented as one or more Intel Core 2 microprocessors. Processing unit 1504 may be capable of executing instructions in an instruction set, such as the x86 instruction set, the POWER instruction set, a RISC instruction set, the SPARC instruction set, the IA-64 instruction set, the MIPS instruction set, or another instruction set. In a second example, processing unit 1504 may be implemented as an ASIC that provides specific functionality. In a third example, processing unit 1504 may provide specific functionality by using an ASIC and by executing software instructions.

Electronic computing device 1500 also comprises a video interface 1506. Video interface 1506 enables electronic computing device 1500 to output video information to a display device 1508. Display device 1508 may be a variety of different types of display devices. For instance, display device 1508 may be a cathode-ray tube display, an LCD display panel, a plasma screen display panel, a touch-sensitive display panel, a LED array, or another type of display device.

In addition, electronic computing device 1500 includes a non-volatile storage device 1510. Non-volatile storage device 1510 is a computer-readable data storage medium that is capable of storing data and/or instructions. Non-volatile storage device 1510 may be a variety of different types of non-volatile storage devices. For example, non-volatile storage device 1510 may be one or more hard disk drives, magnetic tape drives, CD-ROM drives, DVD-ROM drives, Blu-Ray disc drives, or other types of non-volatile storage devices.

Electronic computing device 1500 also includes an external component interface 1512 that enables electronic computing device 1500 to communicate with external components. As illustrated in the example of FIG. 15, external component interface 1512 enables electronic computing device 1500 to communicate with an input device 1514 and an external storage device 1516. In one implementation of electronic computing device 1500, external component interface 1512 is a Universal Serial Bus (USB) interface. In other implementations of electronic computing device 1500, electronic computing device 1500 may include another type of interface that enables electronic computing device 1500 to communicate with input devices and/or output devices. For instance, electronic computing device 1500 may include a PS/2 interface. Input device 1514 may be a variety of different types of devices including, but not limited to, keyboards, mice, trackballs, stylus input devices, touch pads, touch-sensitive display screens, or other types of input devices. External storage device 1516 may be a variety of different types of computer-readable data storage media including magnetic tape, flash memory modules, magnetic disk drives, optical disc drives, and other computer-readable data storage media.

In the context of the electronic computing device 1500, computer storage media includes volatile and nonvolatile, removable and non-removable media implemented in any method or technology for storage of information such as computer readable instructions, data structures, program modules or other data. Computer storage media includes, but is not limited to, various memory technologies listed above regarding memory unit 1502, non-volatile storage device 1510, or external storage device 1516, as well as other RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium that can be used to store the desired information and that can be accessed by the electronic computing device 1500.

In addition, electronic computing device 1500 includes a network interface card 1518 that enables electronic computing device 1500 to send data to and receive data from an electronic communication network. Network interface card 1518 may be a variety of different types of network interface. For example, network interface card 1518 may be an Ethernet interface, a token-ring network interface, a fiber optic network interface, a wireless network interface (e.g., WiFi, WiMax, etc.), or another type of network interface.

Electronic computing device 1500 also includes a communications medium 1520. Communications medium 1520 facilitates communication among the various components of electronic computing device 1500. Communications medium 1520 may comprise one or more different types of communications media including, but not limited to, a PCI bus, a PCI Express bus, an accelerated graphics port (AGP) bus, an Infiniband interconnect, a serial Advanced Technology Attachment (ATA) interconnect, a parallel ATA interconnect, a Fiber Channel interconnect, a USB bus, a Small Computer System Interface (SCSI) interface, or another type of communications medium.

Communication media, such as communications medium 1520, typically embodies computer-readable instructions, data structures, program modules or other data in a modulated data signal such as a carrier wave or other transport mechanism and includes any information delivery media. The term “modulated data signal” refers to a signal that has one or more of its characteristics set or changed in such a manner as to encode information in the signal. By way of example, and not limitation, communication media includes wired media such as a wired network or direct-wired connection, and wireless media such as acoustic, RF, infrared, and other wireless media. Combinations of any of the above should also be included within the scope of computer-readable media. Computer-readable media may also be referred to as computer program product.

Electronic computing device 1500 includes several computer-readable data storage media (i.e., memory unit 1502, non-volatile storage device 1510, and external storage device 1516). Together, these computer-readable storage media may constitute a single data storage system. As discussed above, a data storage system is a set of one or more computer-readable data storage mediums. This data storage system may store instructions executable by processing unit 1504. Activities described in the above description may result from the execution of the instructions stored on this data storage system. Thus, when this description says that a particular logical module performs a particular activity, such a statement may be interpreted to mean that instructions of the logical module, when executed by processing unit 1504, cause electronic computing device 1500 to perform the activity. In other words, when this description says that a particular logical module performs a particular activity, a reader may interpret such a statement to mean that the instructions configure electronic computing device 1500 such that electronic computing device 1500 performs the particular activity.

One of ordinary skill in the art will recognize that additional components, peripheral devices, communications interconnections and similar additional functionality may also be included within the electronic computing device 1500 without departing from the spirit and scope of the present invention as recited within the attached claims.

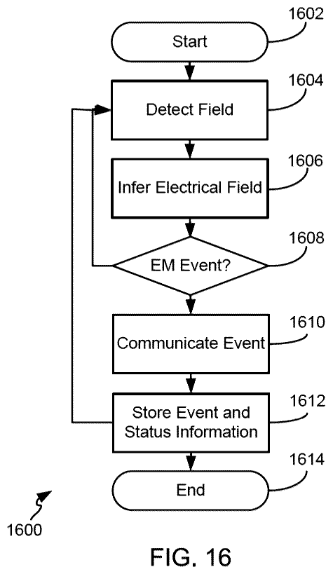

FIG. 16 is a flowchart of methods and systems 1600 for detecting an electromagnetic pulse event, according to a possible embodiment of the present disclosure. Generally, the methods and systems can be performed at least in part using (1) a standard circuit block, as described herein, with respect to either low field or high field systems, and (2) a microprocessor or computing device communicatively connected to the standard circuit block and configured to analyze peak values obtained using the circuit block, as described above.

In the embodiment shown, the methods and systems are instantiated at a start operation 1602, which corresponds to initial setup of one or more detectors at a facility or other location to be monitored, as well as connection of the one or more detectors to other computing devices configured to coordinate detection and analysis of high field and/or low field electromagnetic events, such as EMP/IEMI events.

A field detection operation 1604 corresponds to detection of a field at an antenna that is interconnected with a standard block. As previously described, the field detection operation 1604 can correspond to detection of one or more directional components of a magnetic field using one or more oriented shielded loop magnetic antennas, as described above in connection with high field detection systems in FIGS. 3A-3B and FIGS. 4-10. Alternatively, the field detection operation 1604 can correspond to detection of an electrical field using a short monopole antenna, in the case of detection of a low field electromagnetic event, as described in connection with FIGS. 11-14.

An optional inferential operation 1606 infers an electrical field based on the reading obtained by the field detection operation 1604. The inferential operation 1606 will be performed in the case where a shielded loop magnetic antenna is used to detect a magnetic field, for example in the case of a high field detection system.

An electromagnetic event determination operation 1608 determines whether an electromagnetic event has occurred. Typically the electromagnetic event determination operation 1608 includes sampling a peak value detected using a standard circuit module and associated microprocessor, and performing one or more additional operations on that sample to determine whether a high or low field event occurs. For example, in the case of a high field event, the peak value may be summed or otherwise combined with other inferred electrical field values (e.g., by using the square root of a sum of squares) to arrive at an overall electromagnetic field value, and comparing that value to a preset known threshold, over which it is assumed that a high field event has occurred. In a further example, for low field events, the detected peak value can be directly compared to a known threshold value, and based on that comparison the existence of a low field event can be determined.

If no high or low field event is detected, operational flow can return to the field detection operation 1604 to continue monitoring the electrical and/or magnetic fields present at the detector. However, if a high or low field event is detected, operational flow proceeds to an event communication operation 1610, which communicates the event (e.g., including the field values and time at which the field values were captured) to either memory or a remote system for alarming or further analysis. A storage operation 1612 corresponds to storing the field values and time, as well as information derived from those values or otherwise associated with the detector (e.g., the conclusion regarding whether a high or low field event has occurred, status of one or more electrical or electronic systems associated with the detector, and other sensor information from other associated or interconnected sensors) at a computing system remote from the detector. Operational flow can then continue to the field detection operation 1604, resulting in continued monitoring of the electrical and magnetic fields present at the detector. An end operation 1614 corresponds to completed detection after a desired (e.g. preset or undetermined) amount of time.

Referring to FIG. 16 generally, it is recognized that aspects of the methods and systems can be performed at a detector, while other aspects can be performed at a remote computing system, such as a centralized detector management system (e.g. as illustrated above in connection with FIGS. 1-2).

### Data Acquisition System

In some implementations, the detector itself may include a high-speed data acquisition system configured to capture electromagnetic waveforms generated by detected events. In some embodiments the data acquisition system includes one or more analog-to-digital converters (ADC) configured to sample sensor signals at extremely high rates. The system implements continuous sampling at 1 to 14 billion samples per second (1 to 14 GSa/s), maintaining continuous operation and may analyze data at all times or only once a trigger event occurs. Example sampling rates may include approximately 1 GSa/s (1 billion samples per second), approximately 8 GSa/s, approximately 10 GSa/s, or approximately 20 GSa/s. In certain embodiments sampling rates of 1 to 14 GSa/s may be used to enable accurate reconstruction of signals having frequencies up to approximately 7 GHz. The sampling rate is selected to support frequencies up to approximately 7 GHz based on Nyquist sampling theory, requiring approximately 2-3× sampling rate relative to maximum frequency for accurate reconstruction.

In some implementations the data acquisition system may utilize commercially available high-speed ADC devices capable of sampling rates exceeding 20 GSa/s. For example, a sampling circuit may be implemented using an Analog Devices AD9084 device, which has a max sample rate of 20 GHz. Such a device is available in a dual rate package (quadrature hybrid) which effectively doubles the sampling rate to 40 GHz. Multiple ADC channels may be combined or interleaved to achieve higher effective sampling rates.

In some embodiments, different sampling rates may be used depending on the desired frequency resolution. Examples of Analog to Digital processing speed and frequency or pulse resolution may include: ADC sampling at 1 GHz (1 GSa/S or 1 Sample/nanosecond) can resolve to 500 MHz (Nyquist limit), can detect pulses as short as 3 ns, and one microsecond of data contains 1000 points. ADC sampling at 10 GHz (10 GSa/S or 1 Sample/100 picoseconds) can resolve to 5 GHz (Nyquist limit), can detect pulses as short as 300 ps, and one microsecond of data contains 10,000 points. ADC sampling at 20 GHz (20 GSa/S or 1 Sample/50 picosecond) can resolve to 10 GHz (Nyquist limit), can detect pulses as short as 150 ps, and one microsecond of data contains 20,000 points. High-speed sampling enables capture of electromagnetic events having extremely short durations. For example, events as short as approximately 3 nanoseconds may be detected and recorded.

### Circular Buffer Architecture

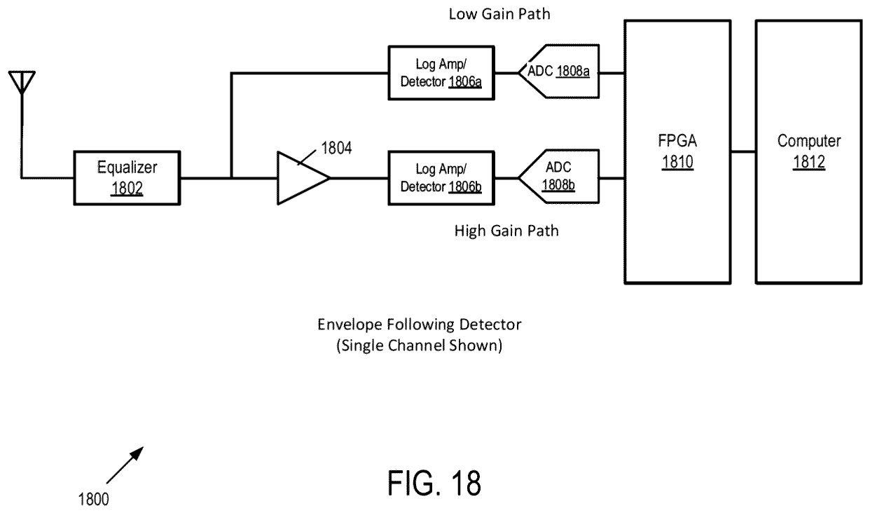

To support continuous monitoring of electromagnetic activity, the detector and data acquisition system may implement a circular buffer memory architecture. Such a circular buffer may be implemented within an FPGA included within such a detector circuit as described below in conjunction with FIG. 18. In some embodiments the circular buffer continuously stores incoming sample data while overwriting the oldest data as new samples are acquired. This approach allows the detector to maintain a continuously updated window of recent signal activity without requiring large memory capacity. The system employs a circular buffer implementation storing several kilobytes of data, continuously overwriting oldest data to maintain efficiency. The buffer uses a single data point rewrite approach rather than complete buffer rewrite to maintain speed. The circular buffer may store a fixed number of samples. In certain implementations the buffer may store approximately 16,000 sample points.

In example embodiments, the circular buffer may be configured so that when an event trigger occurs, approximately 8,000 samples preceding the trigger event are preserved, and approximately 8,000 samples following the trigger event are captured. This arrangement allows reconstruction of the waveform surrounding the detected electromagnetic event. Upon threshold crossing, the system continues sampling for 8,000 additional points while preserving the previous 8,000 points, centering the analysis window around the trigger point.

In some embodiments the circular buffer stores approximately one microsecond of signal data surrounding the trigger point. In some implementations the circular buffer may update individual sample locations sequentially rather than rewriting the entire buffer. Storage requirements are optimized for capturing high-frequency events, with approximately 12.8 MB needed for +100 microsecond trigger windows at 8 GSa/s using double precision floating point storage.

In some embodiments an FPGA may perform high-speed buffer management and frequency analysis operations on captured waveform data. The system implements separate buffer memory for frequency computation using Fast Fourier Transform. This process requires a processing step to analyze the data and perform the FFT on the data in the circular buffer and output the relevant information to the computer. Specialized high-speed hardware like Field Programmable Gate Arrays (FPGA) are well-suited for this purpose.

### Event Detection and Triggering

The system may monitor incoming signals to detect electromagnetic events that exceed predetermined thresholds. The system monitors for local maxima above predetermined thresholds. Event detection may involve monitoring sampled signals for local maxima that exceed a trigger threshold. When a trigger event is detected, the system may preserve previously stored samples from the circular buffer, continue sampling for a defined number of additional samples, and store the complete waveform surrounding the trigger event. The system connects sample points to reconstruct the waveform.

The resulting waveform may represent the electromagnetic signal associated with the event, including the leading edge and peak amplitude. The system is capable of capturing complete pulse shapes including the leading edge of electromagnetic events. The leading wavefront analysis is particularly important as it determines the highest frequency components of the signal.

One or more onboard trigger level(s) trigger a relay output that operates as long as the detectors are powered, independent of the central computer's status. This can be used to trigger an alarm, direct cameras to turn on or record a certain area, turn off power or switch to protected backup power, etc. The detectors are configured to detect an electromagnetic frequency between 10 MHz and 10 GHz and take an action prior to another IEMI attack (attacks will likely be multiple attacks).

### Frequency Analysis

In some embodiments the system performs frequency analysis of detected electromagnetic events. Frequency analysis may be performed using techniques such as Fast Fourier Transform (FFT) processing. FFT processing may enable identification of frequency components within the captured waveform. The system performs Fast Fourier Transform (FFT) analysis to identify frequency components and their relative magnitudes. Frequency analysis may allow the system to determine whether the detected signal represents a single transient pulse, a sequence of pulses, or a continuous wave signal.

The system may perform FFT analysis to identify frequency components up to or in excess of approximately 7 GHz in some implementations. The resulting frequency spectrum may be used to characterize the electromagnetic event and identify dominant frequency components. In some embodiments the system may compensate for variations in frequency response across the sensing path to improve accuracy of relative magnitude measurements between frequency components. The system compensates for frequency response variations across the detection range to improve accuracy of relative magnitude measurements between frequency components. This enhances characterization of multi-frequency events and provides better analysis of complex electromagnetic signatures. Without knowing incoming frequency, the flatness of the antenna/system response is critical to quality of data (field strength). The system includes a passive filtering element to improve this response (determined by testing), relating to the importance of choosing antenna design that has an inherently flat response over the frequency range. If frequency is known, a response curve can be used to correct the field strength measurements to improve accuracy of recorded data.

### Frequency Determination Using Passive Filter Paths

In some embodiments, the system may determine signal frequency using parallel signal paths with different passive filter responses. Another way to determine frequency is to split the antenna channel into two or more signal paths and pass them through passive filters with different frequency responses. This allows for frequency discrimination without needing high speed data acquisition, at the sacrifice of learning the average frequency of a pulse rather than resolving the pulse envelope and being able to use FFT. A sensor signal may be split into two or more signal paths. Each signal path may include a passive filter having a different frequency response. Example filters may include low-pass filters, high-pass filters, band-pass filters, or unfiltered signal paths.

Each filter path attenuates signals differently depending on frequency. By comparing the relative amplitudes of signals passing through the different filters, the system may estimate the frequency of the input signal. The relative output of those filters can be compared to determine the input frequency. In some embodiments, the processor estimates the frequency of the detected signal by comparing the relative amplitudes measured across the filtered signal paths and determining a frequency value based on known attenuation characteristics of the respective filters.

For example, a signal may be split into three paths: an unfiltered path, a high-pass filter path, and a low-pass filter path, as described herein. At least one signal path has a passive filter with known frequency response, and another signal path with a different frequency response. The difference in the outputs determines the frequency. For instance, each antenna channel could have three signal paths: one high-pass filter, one low-pass filter, and one signal path with no passive filter. The relative amplitudes of signals measured at the outputs of these paths may be compared using logarithmic amplifiers and peak detectors. The comparison of the peak values can be used to calculate the input frequency. Because the attenuation characteristics of each filter are known, the system can estimate the input frequency by comparing measured amplitudes. This approach may provide frequency discrimination without requiring extremely high sampling rates. In other embodiments, additional filter paths may be used to improve frequency resolution. Other filter types can be used; the point is that each signal path has a different output at a given frequency, and that difference can be used to determine the input frequency.

Example of frequency determination using passive filters with an input frequency of 5 GHz: The signal path with no filter will have gain defined as 0 dB. The high-pass filter has relatively little attenuation at 5 GHz, maybe 5 dB. The lowpass filter has higher attenuation at 5 GHz, perhaps 30 dB. All three signals are digitized and signal levels compared. The frequency response of the high-pass and low-pass filters is already known. So if the detected signal in the unfiltered path is 5 dB higher than the signal in the high-pass path, and 30 dB higher than the signal in the lowpass path, the frequency must be 5 GHz.

In some implementations the attenuation characteristics of different filters may be compared to estimate signal frequency. For example, an unfiltered signal path may provide a reference signal level while high-pass and low-pass filters attenuate the signal by known amounts at particular frequencies. By comparing the relative amplitudes of the filtered signals, the processor may determine the approximate input frequency.

First order filters cover a large frequency range and have a relatively slow roll-off of 20 dB per decade. This allows a signal path to cover a large frequency range before the signal is attenuated too much to be reliably measured. This is especially useful in this application where the initial signal strength is anticipated to be quite high. Greater resolution of frequency can be achieved by adding parallel signal paths with passive filters with a higher roll-off rate. For instance, instead of a single low-pass filter, there may be two low-pass filter paths with different cutoff frequencies and a higher 40 dB per decade rolloff. Using only these two paths, there will be two frequencies with the same attenuation. Discrimination between these can be achieved by having a third path with a first-order low-pass filter to broadly identify the frequency, and then using that information to determine which second order low-pass filter path has that frequency in its range of response.

### Event Characterization

In example embodiments, the system may characterize electromagnetic events using multiple parameters including peak field strength, frequency spectrum, waveform shape, pulse duration, and repetition rate. The system analyzes frequency content of detected pulses to create unique electromagnetic “fingerprints.” This frequency analysis enables identification of specific weapon types or interference sources and can determine if repeated events come from the same source based on consistent frequency signatures. In some embodiments the system may generate electromagnetic signature profiles based on the frequency content and temporal characteristics of detected signals. These signature profiles may enable identification of similar electromagnetic events across multiple detections. For example, repeated electromagnetic events having similar frequency characteristics may indicate a common source.

### Data Storage and Reporting

Event data collected by detectors may be stored in a database system. The software implementation provides database integration for multi-detector event reporting, supporting various data formats and automated email notifications including pulse graphs and frequency content analysis. Stored data may include waveform samples, frequency spectra, event timestamps, and detector identifiers. The system may generate reports in formats such as CSV, PDF, or other data formats. The system adds email delivery of report when detector trigger point or site trigger level is exceeded, including graph of pulse and time/E-field graph and frequency content for each triggered detector. Automated notifications may be transmitted when detection thresholds are exceeded. The system enables timing comparisons between detectors for source location computation when detector positions are known. The software can communicate using common protocols to integrate with existing network infrastructure (MQTT, etc). Daily backup of data occurs individually for convenience (smaller files), and older files can be overwritten to control storage needed.

Waveform information is stored and transmitted when requested so it does not interfere with other network traffic. Buffer of data points is moved and stored in separate memory to compute frequency content using Fast Fourier Transform. This information, or whole waveform of points, can be sent to the attached central database (has information from each detector in the network). Frequency compensation—the frequency analysis may be used to compensate the input and improve accuracy.

The firmware architecture implements data management processes ensuring successful delivery to computer databases with synchronization capabilities. A detector login window can be added to access file system on the internal SD card. Detector reboot, change IP address, download detector data, and detector time sync can be added in detector setup. The system syncs data from detectors with database to fill in missing data. The software polls detectors for data each second and stores a record of all the detectors attached to the network. This database is accessible for generating reports in various formats (.csv, .pdf, etc), backing up data, using in forensics, sending emails about events, etc.

### Independent Detector Operation

In example embodiments, each detector may continue operating independently even if communication with the central computer is interrupted. The system maintains continuous data collection capability through independent operation from connected computer systems. During communication outages detectors may continue recording event data locally. Detectors continue to record peak field strengths and store onboard to ensure data is collected and stored independent of the central computer's status (e.g., in the case systems are offline or damaged). During power loss or disconnection from external systems, the detector continues to function through an independent clock system that enables automatic resynchronization upon reconnection. When communication is restored the stored data may be synchronized with the central database. The detectors interface with a remote time-keeping element and update internal clock based on that reference. This can be done after communication/power is interrupted to make sure clocks are synced so data collected while not in communication with time reference can be smoothly added to a central record.

A computer attached to the network to poll and receive information from connected detectors can be put into a Faraday cage with filtered power and communication to protect it from EM events and ensure continued data collection and event triggering.

### Signal Acquisition and Processing

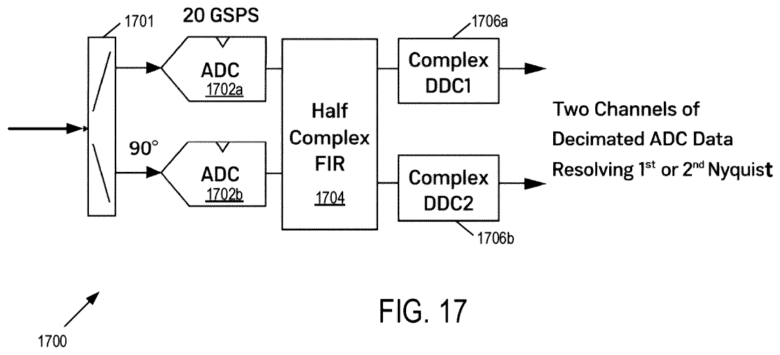

FIG. 17 illustrates an example signal acquisition and digital processing architecture 1700 that may be used in certain embodiments of the electromagnetic field detection system. In the illustrated embodiment, an incoming analog signal is provided to a signal splitter 1701 configured to generate two signal paths having a relative phase offset. In some implementations the splitter produces two signals separated by approximately 90 degrees in phase, thereby forming quadrature signal components.

Each signal path is provided to a corresponding analog-to-digital converter (ADC) 1702a-b, respectively, operating at a high sampling rate. In one example implementation the ADCs operate at approximately 20 gigasamples per second (GSPS), although other sampling rates may be used depending on system requirements.

The digitized outputs of the ADCs are provided to a finite impulse response (FIR) filtering stage 1704, which may be implemented as a half-complex FIR filter. The filtering stage may perform signal conditioning operations including filtering, decimation, and preparation of the sampled data for further digital processing.

Following filtering, the signals are processed by respective digital down-conversion (DDC) modules 1706a-b. In the illustrated embodiment two complex digital downconverters (DDC1 and DDC2) generate corresponding baseband or near-baseband representations of the sampled signal. The digital down-conversion stages may perform operations including frequency translation, decimation, and complex signal generation.

The resulting outputs may include multiple channels of decimated ADC data suitable for further analysis by downstream signal processing components. In some embodiments the resulting channels may correspond to signals resolving frequencies within the first or second Nyquist zones of the analog-to-digital converters. The digital down-conversion stages may process signals originating in multiple Nyquist zones of the ADC sampling architecture.

The processed digital data may subsequently be provided to additional signal processing stages, such as waveform reconstruction, event detection, or frequency analysis modules including Fast Fourier Transform (FFT) processing as described elsewhere in the present disclosure.

FIG. 18 illustrates an example envelope-following detection architecture 1800 that may be implemented in certain embodiments of the electromagnetic field detection system. The figure shows one of multiple detection channels that may be used in the system.

In the illustrated embodiment, an input signal received from a sensor or antenna is first provided to an equalization stage (shown as equalizer 1802) configured to compensate for frequency response variations of the sensing element and associated signal path. The equalized signal is then divided into multiple parallel processing paths.

A first signal path forms a low-gain processing path in which the equalized signal is provided directly to a logarithmic amplifier and detector circuit 1806b. The logarithmic amplifier may compress the dynamic range of the input signal and generate an output proportional to the envelope magnitude of the detected electromagnetic signal.

A second signal path forms a high-gain processing path in which the equalized signal is first amplified by an amplifier stage 1804 and then provided to a second logarithmic amplifier and detector circuit 1806a. The amplifier stage increases the sensitivity of this signal path to lower-amplitude electromagnetic signals.

Outputs from the logarithmic detector circuits 1806a-b are provided to corresponding analog-to-digital converters (ADCs) 1808a-b. In the illustrated embodiment the ADCs operate at approximately 1 GHz sampling rate, although other sampling rates may be used depending on implementation.

Digital outputs from the ADCs 1808a-b are provided to a field programmable gate array (FPGA) 1810 that performs signal processing operations including envelope analysis, event detection, and data management. The FPGA 1810 may analyze the detected signal envelopes from the low-gain and high-gain paths to determine characteristics of detected electromagnetic events. Processed data may then be transmitted to a computer system 1812 for further analysis, storage, visualization, or correlation with data from additional detector units.

The use of multiple gain paths allows the system to detect electromagnetic events across a wide dynamic range by enabling detection of both high-amplitude and low-amplitude signals without saturation of the detection circuitry.

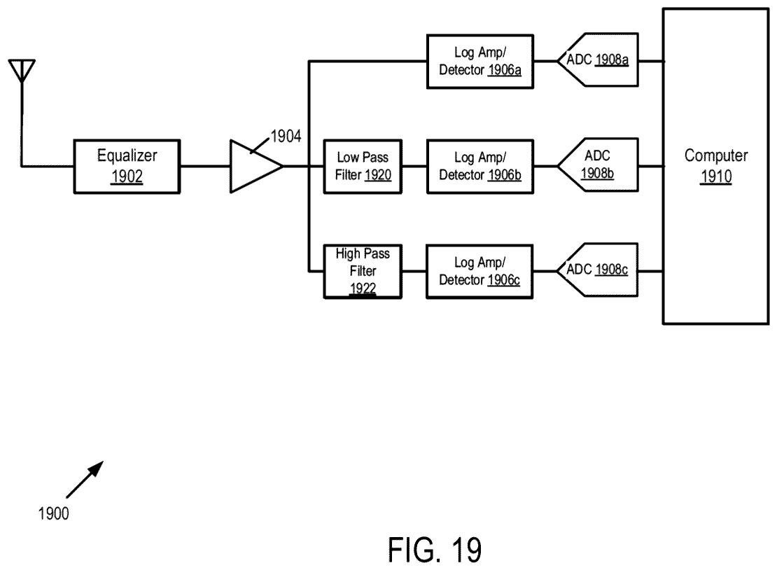

FIG. 19 illustrates an example signal processing architecture 1900 that may be used to determine characteristics of detected electromagnetic signals using multiple parallel signal paths having different frequency responses.

In the illustrated embodiment, an input signal received from a sensing antenna is provided to an equalization stage 1902 configured to compensate for frequency response variations of the sensing element and associated signal path. The equalized signal is then amplified by an amplifier stage 1904 and distributed to multiple parallel signal processing paths.

A first signal path provides the amplified signal directly to a logarithmic amplifier and detector circuit 1906a, forming an unfiltered reference signal path. A second signal path includes a high-pass filter (HPF) 1922 configured to preferentially pass higher frequency components of the input signal. A third signal path includes a low-pass filter (LPF) 1920 configured to preferentially pass lower frequency components of the input signal.

Each signal path includes a corresponding logarithmic amplifier and detector circuit 1906a-c, respectively, that produces an output signal representative of the envelope magnitude of the signal within that path. The outputs of the logarithmic detectors are then provided to respective peak detector circuits (also encompassed by 1906a-c), which capture peak values of the detected signal envelopes during a detection interval.

The peak detector outputs are digitized using corresponding analog-to-digital converters (ADCs) 1908a-c and provided to a computing system 1910 for analysis. By comparing the relative amplitudes of the signals received from the different signal paths, the computing system can estimate characteristics of the detected electromagnetic signal, including an approximate signal frequency or frequency range.

Because each signal path exhibits a different frequency response, the relative signal amplitudes measured across the paths vary depending on the frequency content of the input signal. This multi-path architecture therefore enables frequency discrimination without requiring extremely high-speed waveform sampling. In certain embodiments, the comparison of peak values across the signal paths may be used to estimate the input signal frequency using known attenuation characteristics of the respective filters.

The illustrated architecture may be implemented for each sensor channel of the detector system, allowing multiple electromagnetic field sensing channels to independently estimate signal frequency characteristics.

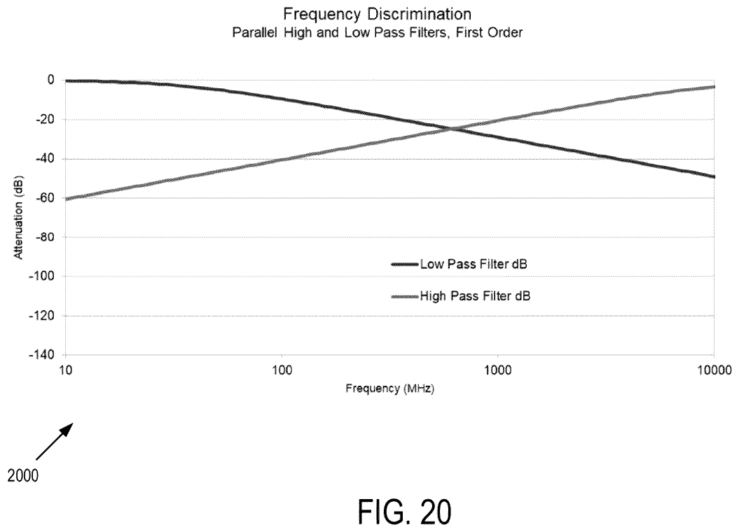

FIG. 20 illustrates an example frequency response chart 1900 for a pair of filter paths that may be used in a multi-path signal processing architecture for frequency discrimination. In the illustrated example, the system employs parallel low-pass and high-pass filters, each having a first-order response characteristic.

The horizontal axis represents signal frequency, shown on a logarithmic scale from approximately 10 MHz to 10,000 MHz, while the vertical axis represents attenuation in decibels (dB). The curve representing the low-pass filter response shows relatively low attenuation at lower frequencies and progressively greater attenuation as frequency increases. Conversely, the curve representing the high-pass filter response shows relatively high attenuation at lower frequencies and progressively lower attenuation as frequency increases.

Because the attenuation characteristics of the two filter paths vary in opposite directions as a function of frequency, the relative amplitudes of signals measured at the outputs of the respective filter paths depend on the frequency content of the input signal. By comparing the signal magnitudes obtained from the parallel filter paths, the system may estimate the approximate frequency or frequency range of the detected electromagnetic signal.

In certain embodiments, the attenuation curves illustrated in FIG. 20 correspond to first-order filter responses, which may provide gradual roll-off characteristics over a broad frequency range. Such filter responses may be advantageous in applications where the input signal strength is sufficiently large to allow reliable detection even when the signal is partially attenuated.

In other embodiments, filters having different orders, cutoff frequencies, or response characteristics may be used to provide different frequency discrimination behavior. The use of multiple parallel filter paths with known response characteristics allows the system to estimate signal frequency without requiring full high-speed waveform sampling of the input signal.

### Single Pulse Events, Pulse Train and Continuous Wave Detection

The system may be capable of detecting both single electromagnetic pulses and sequences of repeated pulses. The system can process events as short as 3 nanoseconds in duration. In certain embodiments the detector may process pulse trains having repetition rates up to approximately 1 kHz, meaning it can handle up to 1000 pulses per second. The system maintains sufficient processing speed to capture multiple events in sequence, with dead time between captures limited only by computational processing time. This capability enables analysis of coordinated attacks or repeated use of electromagnetic weapons. The system may also detect continuous wave electromagnetic signals when present, though these are less common in EMP/IEMI scenarios. The frequency analysis provides detailed characterization of continuous wave components through FFT analysis. Frequency analysis may enable differentiation between transient pulses, pulse trains, and continuous signals. The system can distinguish between continuous wave signals and pulsed attacks through its frequency analysis capabilities. The system is capable of detecting and analyzing repeated pulse events and continuous waves (10 Hz or higher pulse frequency) and uses that to produce more accurate pulse waveform.

### Processing Architecture

In accordance with some processing examples described herein, processing operations may be divided into multiple stages. The system implements local processing within the detector to minimize data transfer requirements. Computational processing occurs after capture to maintain sampling speed. In some embodiments the system implements separate processing paths for event detection, waveform capture, and frequency analysis. There are separate processing paths for peak detection and frequency analysis. The system maintains original peak detection capability while adding frequency analysis. Separating these processing tasks may reduce latency and allow continuous signal monitoring while previously captured events are being analyzed. High-speed signal processing tasks may be implemented using hardware such as field programmable gate arrays (FPGAs) or dedicated digital signal processors. The term processor herein may refer to a microprocessor, FPGA, digital signal processor, or other computing device.

The processing architecture implements separate paths for peak detection and frequency analysis, ensuring minimal dead time between event captures while maintaining the ability to perform sophisticated signal processing. The system implements a two-stage analysis approach separating capture and processing operations, with dedicated processing resources for frequency analysis and separate buffers for continuous capture and analysis.

### User Interface and Visualization

The system may include software that provides a graphical user interface for monitoring electromagnetic events. The system implements a comprehensive visualization interface featuring dynamic icon color changes based on threshold events, integrated building schematic displays, and trigger location indication capabilities. The interface may display, for example, detector locations, event alerts, signal strength information, and frequency content of detected events. The interface provides real-time status updates and allows operators to quickly assess threat conditions through visual cues.

In some embodiments the interface may display building schematics or maps with indicators showing detector locations and triggered events. The user interface serves as a central data collection point, providing visual indication of detector status, event characteristics, and potential threat sources. The interface displays detector locations on configurable maps or layouts with customizable visual cues and zone-based triggering capabilities. Visual indicators such as color-changing icons may be used to highlight detected electromagnetic events. Some may be inside, some outside. Some may be in controlled/shielded area. The system adds ability to place zones-triggers in certain zones are treated differently by visual cue, reports sent, etc. Can add relay outputs at multiple levels based on this information to trigger alarms or events. Historical event data may be stored for forensic analysis and reporting. Multiple detectors can be monitored simultaneously through the centralized interface, enabling rapid identification of coordinated attacks or multiple threat sources.

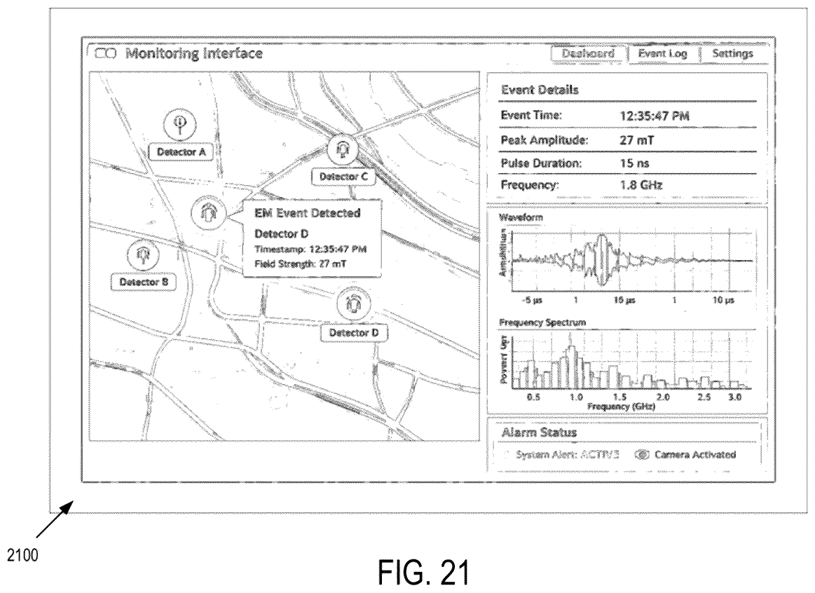

FIG. 21 illustrates one example graphical user interface 2100 that may be used to monitor electromagnetic detection events generated by one or more detector units of the electromagnetic field detection system. The interface may be displayed on a monitoring computer or other computing device configured to receive event data from one or more detectors, such as the computing devices described above.

In the illustrated embodiment, the interface includes a map display region showing a geographic area in which multiple detector units are deployed. Detector locations may be represented by graphical indicators identifying individual detectors, such as Detector A, Detector B, Detector C, and Detector D. When an electromagnetic event is detected by one or more detectors, the interface may display a corresponding event indicator on the map. The event indicator may include information identifying the detecting device and basic event parameters, such as time of detection and measured field strength.

The interface further includes an event information panel that presents additional details associated with a detected event. Example information displayed in this panel may include an event timestamp, measured peak field amplitude, pulse duration, and estimated signal frequency. These values may be derived from waveform capture and signal analysis operations performed by the detector system.

In some embodiments, the interface may also include graphical plots representing characteristics of the detected electromagnetic signal. For example, a waveform display may present a time-domain representation of the captured signal surrounding a detected event. A frequency spectrum display may present the frequency-domain characteristics of the signal, such as those generated by a Fast Fourier Transform or other spectral analysis technique.

The interface may additionally include a system status or alarm indicator that provides information regarding system state or triggered alerts. For example, the interface may indicate when a system alert condition is active and may identify associated automated responses, such as activation of cameras or other monitoring equipment.

The graphical user interface illustrated in FIG. 21 therefore enables an operator to monitor detector status, visualize electromagnetic events, and review signal characteristics associated with detected electromagnetic disturbances.

### Alternative Embodiments

Various modifications and alternative implementations may be employed without departing from the scope of the invention. For example, the system may utilize different sensor types, sampling architectures, processing algorithms, or communication systems depending on the requirements of a particular application. The disclosed embodiments therefore illustrate principles of the invention rather than limiting its scope.

Additionally, although the present disclosure has been described with reference to particular means, materials and embodiments, from the foregoing description, one skilled in the art can easily ascertain the essential characteristics of the present disclosure and various changes and modifications may be made to adapt the various uses and characteristics without departing from the spirit and scope of the present invention as set forth in the following claims.

1. An electromagnetic field detection and analysis system comprising:
a housing comprising a Faraday cage construction;
three orthogonal magnetic field sensors, the orthogonal magnetic field sensors comprising shielded loop magnetic antennas configured to detect electromagnetic fields with strengths ranging from 100 V/m to 100,000 V/m and frequencies between 10 MHz and 10 GHz;
a data acquisition system positioned within the housing and operatively connected to the three orthogonal magnetic field sensors, the data acquisition system operating at or above 8 billion samples per second; and
a circular buffer memory system electrically connected to the data acquisition system and configured to store 16,000 sample points, comprising 8,000 samples before and 8,000 samples after a trigger event.

2. The electromagnetic field detection and analysis system of claim 1, further comprising a computing device positioned within the Faraday cage construction and configured to perform real-time analysis on acquired data up to and exceeding approximately 7 GHz.

3. The electromagnetic field detection and analysis system of claim 1, further comprising an EMP filter grounded to the housing.

4. The electromagnetic field detection and analysis system of claim 1, wherein the housing comprises compartmentalized interior spaces configured to reduce electromagnetic noise interference.

5. The electromagnetic field detection and analysis system of claim 1, wherein the system is configured to process electromagnetic pulse trains up to 1 kHz repetition rate.

6. The electromagnetic field detection and analysis system of claim 1, further comprising a CMOS battery having a life expectancy of at least 3 years.

7. The electromagnetic field detection and analysis system of claim 1, further comprising a rechargeable battery with capacity to operate the system for several minutes or until power is restored.

8. The electromagnetic field detection and analysis system of claim 1, further comprising a computing device configured to:
detect and analyze electromagnetic events as short as 3 nanoseconds;
maintain approximately 1 microsecond of data around a peak detected within the electromagnetic events; and
perform real-time frequency analysis identifying specific electromagnetic signatures within the electromagnetic events.

9. The electromagnetic field detection and analysis system of claim 1, further comprising building perimeter software configured to:
provide real-time visual indication of detected electromagnetic events;
display color-changing icons based on threshold detection;
provide directional indication based on multiple detector readings; and
maintain historical data storage for forensic analysis.

10. The electromagnetic field detection and analysis system of claim 1, wherein the three orthogonal magnetic field sensors are configured to:
provide three-dimensional field measurement capability;
utilize magnetic field detection to infer electric field strength; and
maintain detection capabilities without requiring sacrificial elements.

11. The electromagnetic field detection and analysis system of claim 1, wherein the housing comprises:
a body having an anodized aluminum exterior;
masked conduction points on the anodized aluminum exterior;
a body serving as both a heat sink and ground plane; and
an outdoor rated construction configured to maintain operation in various weather conditions.

12. A method for electromagnetic field detection and analysis comprising:
continuously monitoring electromagnetic fields using three orthogonal magnetic field sensors;
acquiring electromagnetic field data at a rate of at least 8 billion samples per second at sensor circuitry positioned within a Faraday cage construction;
storing at least 16,000 sample points in a circular buffer memory system associated with the sensor circuitry;
performing real-time Fast Fourier Transform (FFT) analysis on the acquired data up to or exceeding approximately 7 GHz;
identifying specific electromagnetic signatures based on the real-time Fast Fourier Transform (FFT) analysis; and
providing visual indication of detected electromagnetic events through a building perimeter software interface.

13. The method of claim 12, further comprising:
storing at least 8,000 samples before a trigger event;
storing at least 8,000 samples after the trigger event; and
maintaining approximately 1 microsecond of data both before and after peak detection.

14. The method of claim 12, further comprising:
processing electromagnetic pulse trains up to 1 kHz repetition rate;
detecting and analyzing the electromagnetic events as short as 3 nanoseconds; and
performing continuous high-speed data buffering during event processing.

15. A system for electromagnetic threat detection comprising:
a Faraday cage housing with compartmentalized interior spaces;
three orthogonal magnetic field sensors configured for three-dimensional field measurement;
a high-speed data acquisition and analysis system comprising:
a data acquisition component operating at 8 billion samples per second;
a circular buffer memory system storing 16,000 sample points;
a computing device performing real-time frequency analysis up to 7 GHz;
an EMP filter grounded to the Faraday cage housing; and
building perimeter software providing real-time threat assessment and visualization.

16. The system of claim 15, wherein the three orthogonal magnetic field sensors are configured to:
detect electromagnetic fields with strengths ranging from 100 V/m to 100,000 V/m without attenuation;
analyze frequencies between 10 MHz and 10 GHz; and
maintain detection capabilities at distances up to 100 meters.

17. The system of claim 15, wherein the computing device is configured to:
perform continuous high-speed data buffering;
conduct real-time frequency analysis;
enable multiple sequential event detection; and
identify specific electromagnetic signatures associated with particular devices or weapons.

18. The system of claim 15, wherein the building perimeter software is configured to:
display color-changing icons based on threshold detection;
provide directional indication based on multiple detector readings;
maintain historical data storage for forensic analysis; and
display building schematics with integrated threat indication overlays.

19. A method for correlating electromagnetic events across multiple sites comprising: deploying multiple electromagnetic field detection systems at different locations, each system comprising:
three orthogonal magnetic field sensors;
a high-speed data acquisition system;
a circular buffer memory system;
a computing device performing real-time frequency analysis;
synchronizing timing data across the multiple electromagnetic field detection systems;
correlating electromagnetic event detections across the multiple electromagnetic field detection systems; and
providing unified threat assessment through building perimeter software.

20. The method of claim 19, further comprising:
maintaining independent clock operation with synchronization capability across the multiple electromagnetic field detection systems;
comparing frequency signatures detected at different locations; and
determining directional information based on correlated detections.

21. The method of claim 19, wherein each system maintains detection capabilities for:
field strengths ranging from 100 V/m to 100,000 V/m without attenuation;
frequencies between 10 MHz and 10 GHz; and
electromagnetic events as short as 3 nanoseconds.

22. A system for electromagnetic field detection comprising:
a housing with a weather resistant exterior configured for outdoor operation;
three orthogonal magnetic field sensors connected to circuitry positioned within the housing;
a high-speed data acquisition system included in the circuitry and operating at or above 8 billion samples per second;
a computing device configured to perform real-time frequency analysis;
wherein the system is configured to:
detect electromagnetic fields without requiring sacrificial elements;
maintain operation in various weather conditions; and
provide continuous monitoring during event processing.

23. The system of claim 22, further comprising:
compartmentalized interior spaces configured to reduce electromagnetic noise;
masked conduction points on the anodized aluminum exterior;
a body serving as both heat sink and ground plane; and
an EMP filter grounded to the body.

24. The system of claim 22, wherein the computing device is configured to:
perform Fast Fourier Transform analysis up to approximately 7 GHz;
identify specific electromagnetic signatures;
maintain historical data for forensic analysis; and
provide real-time threat assessment through building perimeter software.

25. A method for electromagnetic signature identification comprising:
detecting electromagnetic fields using three orthogonal magnetic field sensors;
acquiring field data at 8 billion samples per second;
performing real-time frequency analysis up to 7 GHz;
comparing detected frequency signatures against known electromagnetic signatures; and
providing threat assessment based on signature matching.

26. The method of claim 25, further comprising:
maintaining detection capabilities in various weather conditions;
operating without sacrificial elements; and
providing continuous monitoring during event processing.

27. The method of claim 25, wherein comparing detected frequency signatures comprises: analyzing frequency components up to 7 GHz;
evaluating pulse train characteristics up to 1 kHz repetition rate; and
correlating detected signatures with known device or weapon signatures.

28. An electromagnetic field detection and analysis system comprising:
a housing comprising a Faraday cage construction with an exterior;
three orthogonal magnetic field sensors connected to circuitry positioned within the housing, the orthogonal magnetic field sensors comprising shielded loop magnetic antennas configured to detect electromagnetic fields with strengths within a range of 100 V/m to 100,000 V/m and frequencies between 10 MHz and 10 GHz,
wherein each of the shielded loop magnetic antennas includes an input channel split into at least two signal paths, the at least two signal paths having a passive frequency response different from one another;
wherein the circuitry positioned within the housing includes:
a logarithmic amplifier electrically connected to the at least two signal paths associated with one of the shielded loop magnetic antennas, the logarithmic amplifier being configured to generate amplified signals within a signal range based on input signals received on each signal path of the at least two signal paths; and
a peak detector receiving the amplified signals from the logarithmic amplifier and configured to capture a peak value of the signals during a detection period.

29. The electromagnetic field detection and analysis system of claim 28, wherein a magnitude of the amplified signals from each signal path of the at least two signal paths in a channel comprising the at least two signal paths are compared to determine an input frequency.

30. The electromagnetic field detection and analysis system of claim 28, wherein the passive frequency response on one or more of the at least two signal paths is flat with no attenuation.

31. The electromagnetic field detection and analysis system of claim 28, wherein the passive frequency response on a signal path of the at least two signal paths is a low pass filter with a known frequency response.

32. The electromagnetic field detection and analysis system of claim 28, wherein the passive frequency response on a signal path of the at least two signal paths is a high pass filter with a known frequency response.

33. The electromagnetic field detection and analysis system of claim 28, further comprising a microprocessor communicatively connected to the peak detector of a signal path among the at least two signal paths and used to calculate a frequency of a received signal by comparing the peak value received on the signal path and using a known frequency response of the signal path.
